(19) United States
(12) Patent Application Publication
(10) Pub. No.: US 2013/0112927 A1
(43) Pub. Date: May 9, 2013

(54) COMPOSITION, AND FILM, CHARGE TRANSPORTING LAYER, ORGANIC ELECTROLUMINESCENCE DEVICE USING THE COMPOSITION, AND METHOD FOR FORMING CHARGE TRANSPORTING LAYER

(71) Applicant: FUJIFILM CORPORATION, Tokyo (JP)

(72) Inventors: Naoyuki Hayashi, Kanagawa (JP); Yasunori Yonekuta, Kanagawa (JP); Koji Takaku, Kanagawa (JP); Saki Oosumi, Kanagawa (JP); Ryo Nishio, Kanagawa (JP)

(73) Assignee: FUJIFILM CORPORATION, Tokyo (JP)

(21) Appl. No.: 13/729,689

(22) Filed: Dec. 28, 2012

Related U.S. Application Data
(63) Continuation of application No. PCT/JP2011/064835, filed on Jun. 28, 2011.

(30) Foreign Application Priority Data
Jun. 30, 2010 (JP) 2010-150596

(51) Int. Cl. H01L 51/00

(52) U.S. Cl. CPC H01L 51/0094
USPC 252/500; 427/66

(57) ABSTRACT

Provided are a composition useful for manufacturing an organic electroluminescence device that has improved efficiency and durability in an organic electroluminescence device in which a siloxane polymer is used as a material for organic electroluminescence device, the composition including (A) a siloxane polymer having a charge transporting moiety at a side chain thereof, (B) at least one crosslinking agent, and (C) a solvent, a film, a charge transporting layer, and an organic electroluminescence device which use the composition, and a method for forming a charge transporting layer.

### TECHNICAL FIELD

The present invention relates to a composition, a film, a charge transporting layer and an organic electroluminescence device using the composition, and a method for forming a charge transporting layer. The composition of the present invention is useful as a composition for organic electroluminescence device.

### BACKGROUND ART

Studies have been actively conducted on an organic electroluminescence device (hereinafter, also referred to as OLED or an organic EL device) as a device using organic materials, a transistor using organic semiconductors and the like. In particular, organic electroluminescence devices are expected to be developed for large-area full-color display devices of a solid emission type or illumination applications as an inexpensive large-area surface light source. In general, an organic electroluminescence device is constituted with an organic layer including a light emitting layer and a pair of counter electrodes interposing the organic layer therebetween. When a voltage is applied to such an organic electroluminescence device, electrons are injected from a cathode, and holes are injected from an anode, respectively into the organic layer. The electrons and the holes are recombined in the light emitting layer, and at the time when an energy level returns from a conduction band to a valence band, energy is released as light, thereby obtaining light emission.

The organic EL device may be manufactured by film-forming a light emitting layer and other organic layers by means of, for example, a dry method such as vapor deposition and the like, or a wet method such as application and the like, and the wet method is given attention from the viewpoint of productivity and the like.

In a case where an organic EL device having a plurality of organic layers is manufactured by an application method, when an application liquid for forming one organic layer is applied on another organic layer, the lower layer is dissolved, thereby causing a problem of layer mixing.

In particular, when a light emitting layer is film-formed on a material with a low band gap, such as a hole injection layer, a hole transporting layer and the like by means of an application method, the material with a low band gap and the light emitting layer are mixed together, thereby reducing light emission efficiency.

In order to prevent the lower layer from being dissolved, a method of using a polymer material in the lower layer, or a method of applying the lower layer and then film-curing the lower layer by crosslinking has been performed. However, in general-purpose polymer materials such as acrylate, methacrylate or the like, due to effects of a polymerization initiator incorporated in a small amount during synthesis, the device performance deteriorates. Further, even in a polymer material in which a polymerization initiator such as polyether or the like is not used, materials in the upper layer are incorporated by swelling.

Meanwhile, even in the method of crosslinking and film-curing after application, adverse effects of a polymerization initiator on a device are problematic, and thus a heat polymerization method by a styryl compound and the like has been reviewed, but there are problems in that a high temperature and a long time are required for film-curing, and the like.

With respect to the problem of the polymerization initiator, there is a siloxane polymer as a polymer compound which does not need to use a polymerization initiator during the polymerization.

As a siloxane polymer used as a material for organic electroluminescence device, for example, Patent Document 1 describes a hole transportable siloxane polymer prepared by a sol-gel reaction by mixing a silane coupling agent having arylamine moieties with any silane coupling agent.

In addition, Patent Document 2 describes a siloxane polymer (crosslinking ratio 100%) having 2 or more arylamine moieties and in which silicon atoms in the siloxane polymer are directly bonded to the moieties and crosslinked at the moieties.

### RELATED ART

### Patent Document

Patent Document 1: Japanese Patent No. 3640444
Patent Document 2: Japanese Patent Application Laid-Open No. 2000-80167

### DISCLOSURE OF INVENTION

### Problems to Be Solved by the Invention

However, organic electroluminescence devices in which a siloxane polymer is used as a material for organic electroluminescence device in the related art are insufficient in terms of efficiency and durability, and thus further improvements thereof were demanded.

A problem of the present invention is to solve the above-described problem in the related art and to achieve the following objects.

That is, an object of the present invention is to provide a composition which is useful for manufacturing an organic electroluminescence device that has improved efficiency and durability in an organic electroluminescence device in which a siloxane polymer is used as a material for organic electroluminescence device.

Further, another object of the present invention is to provide a film, a charge transporting layer and an organic electroluminescence device using the composition, and a method for forming a charge transporting layer.

### Means for Solving the Problems

In consideration of the above-described circumstances, the present inventors have intensively studied, and as a result, found that the problem may be solved by using a composition containing a siloxane polymer having a charge transporting moiety at the side chain thereof, at least one crosslinking agent and a solvent.

That is, the means for solving the problem are as follows.

[1] A composition containing (A) a siloxane polymer having a charge transporting moiety at a side chain thereof, (B) at least one crosslinking agent, and (C) a solvent.

[2] The composition as described in [1] above, in which the at least one crosslinking agent (B) includes an alkoxysilane compound or a chlorosilane compound.

[3] The composition as described in [2] above, in which the alkoxysilane compound or the chlorosilane compound has a charge transporting moiety.

[4] The composition as described in [2] or [3] above, in which the alkoxysilane compound or the chlorosilane compound has a vinyl group.

[5] The composition as described in any one of [1] to [4] above, in which the at least one crosslinking agent (B) includes a compound having a plurality of vinyl groups.

[6] The composition as described in [5] above, in which the compound having a plurality of vinyl groups also has a charge transporting moiety.

[7] The composition as described in any one of [1] to [6] above, in which the charge transporting moiety of the side chain of the siloxane polymer (A) is a hole transporting moiety.

[8] The composition as described in any one of [1] to [7] above, in which the solvent (C) contains an aromatic hydrocarbon-based solvent as a first solvent, and a second solvent having a relative permittivity higher than that of the first solvent.

[9] A film formed by applying the composition as described in any one of [1] to [8] above and heating the applied composition.

[10] A charge transporting layer which is the film as described in [9] above.

[11] An organic electroluminescence device containing the charge transporting layer as described in [10] above.

[12] A method for forming a charge transporting layer, including: applying the composition as described in any one of [1] to [8] above and heating the applied composition.

### Effects of Invention

According to the present invention, it is possible to provide a composition which is useful for manufacturing an organic electroluminescence device that has improved efficiency and durability in an organic electroluminescence device in which a siloxane polymer is used as a material for organic electroluminescence device.

Further, according to the present invention, it is possible to provide a film using the composition, a charge transporting layer, an organic electroluminescence device, and a method for forming a charge transporting layer.

### BRIEF DESCRIPTION OF DRAWINGS

FIG. 1 is a schematic view illustrating an example of a layer configuration of an organic electroluminescent device according to the present invention.

### EMBODIMENTS FOR CARRYING OUT THE INVENTION

Hereinafter, the present invention will be described in detail. Meanwhile, in the present specification, “to” indicates a range including the numerical values described before and after “to” as a minimum value and a maximum value, respectively.

The composition of the present invention contains (A) a siloxane polymer having a charge transporting moiety at a side chain thereof, (B) at least one crosslinking agent, and (C) a solvent.

The reason why the use of the composition of the present invention is useful for the manufacture of an organic electroluminescence device in which efficiency and durability are improved is not clear, but is assumed as follows.

The composition of the present invention is applied and then heated during the film formation, and thus a crosslinking reaction proceeds between molecules of the crosslinking agent (B) and/or between the crosslinking agent (B) and the siloxane polymer (A) having a charge transporting moiety at a side chain thereof. It is thought that the glass transition temperature (Tg) of the film becomes higher than that of a film formed during the film formation of a composition which does not contain the crosslinking agent (B) due to the crosslinking reaction. Accordingly, it is possible to improve the strength of the film and maintain an appropriate distance interval between charge transporting moieties included in the side chain of the siloxane polymer (A), and thus when a film obtained by such a film formation is used as a layer of an organic electroluminescence device, it is thought that efficiency and durability of the device are improved.

The composition according to the present invention is, for example, a composition for organic electroluminescence device, and typically a composition for forming a hole transporting layer. Hereinafter, the constitution of the composition will be described.

[1] (A) A siloxane polymer having a charge transporting moiety at a side chain thereof.

As a siloxane polymer which may be used in the present invention, any known polymer may be used as long as the polymer has a charge transporting moiety at the side chain of the polymer.

Here, the charge transporting moiety means a structural moiety having a hole mobility of 10⁻⁶ cm/Vs to 100 cm/Vs or an electron mobility of 10⁻⁶ cm/Vs to 100 cm/Vs. Examples of the charge transporting moiety include a hole transporting moiety, an electron transporting moiety, a bipolar transportable moiety and the like.

The charge transporting moiety at the side chain of the siloxane polymer (A) of the present invention is preferably a hole transporting moiety.

The siloxane polymer (A) of the present invention preferably has a structure represented by the following Formula (1-a) or the following Formula (1-b).

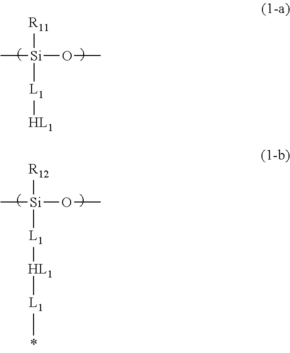

(In Formula (1-a) and Formula (1-b), each of R₁₁ and R₁₂ independently represents an alkyl group or an aryl group, each of L₁ independently represents a single bond or a divalent linking group, and each of HL₁ independently represents a charge transporting moiety. * represents a moiety bonded to a silicon atom of the siloxane polymer)

In Formula (1-a) and Formula (1-b), each of R₁₁ and R₁₂ independently represents an alkyl group or an aryl group.

The alkyl group is preferably an alkyl group having 1 to 8 carbon atoms, and more preferably an alkyl group having 1 to 6 carbon atoms, and specifically, a methyl group, an ethyl group and a t-butyl group are preferred, and a methyl group is more preferred.

The aryl group is an aryl group having preferably 6 to 20 carbon atoms, and more preferably 6 to 12 carbon atoms, and specific examples thereof include a phenyl group, a naphthyl group, a biphenyl group, an anthryl group and the like, and a phenyl group and a naphthyl group are preferred.

R₁₁ and R₁₂ are preferably an alkyl group.

L₁ represents a single bond or a divalent linking group. A divalent linking group represented by L₁ is preferably a divalent hydrocarbon group which may include an oxygen atom, a sulfur atom or a nitrogen atom, and more preferably an alkylene group, a cycloalkylene group, an arylene group and a divalent group obtained by combination thereof, which may include an oxygen atom, a sulfur atom or a nitrogen atom.

In addition, the number of carbons included in the divalent linking group represented by L₁ is preferably 3 or more. When the number of carbons of the divalent linking group L₁ is less than 3, the group is sterically crowded, and thus there is a problem in that the side chain introduction rate is reduced. When the number of carbons is 12 or less, since the ratio of insulating moieties is not extremely increased, it is preferred in that the charge transporting property of the siloxane compound may be enhanced. Considering these facts, the number of carbons of the divalent linking group L is preferably 3 to 12.

HL₁ represents a charge transporting moiety. Examples of the charge transporting moiety represented by HL₁ include a hole transporting moiety, an electron transporting moiety, a bipolar transportable moiety and the like. Meanwhile, in a hole injection layer, a hole transporting layer, a charge blocking layer, an exciton blocking layer and the like, in which crosslinking and film-curing is needed, HL1 is preferably a hole transporting moiety.

Examples of the hole transporting moiety include a monovalent group or a divalent linking group derived from derivatives such as NPD, TPD and the like, which are triarylamine derivatives, or known compounds such as carbazole derivatives, metal phthalocyanine derivatives, pyrrole derivatives, thiophene derivatives and the like, and a triarylamine derivative and a carbazole derivative are preferred.

Examples of the electron transporting moiety include a monovalent group or a divalent linking group derived from known compounds such as oxadiazole derivatives, triazine derivatives, phenanthrene derivatives, triphenylene derivatives, silole derivatives, Al complexes, Zn complexes and the like.

Examples of the bipolar transportable moiety include a monovalent group or a divalent linking group derived from known compounds such as benzoxazole derivatives, anthracene derivatives, perylene derivatives, tetracene derivatives and the like.

The content of the structure (repeating unit) represented by Formula (1-a) or Formula (1-b) in the siloxane polymer (A) is preferably 5 mol % to 99 mol %, more preferably from 50 mol % to 95 mol %, and still more preferably from 75 mol % to 90 mol %, based on the total repeating units in the siloxane polymer (A).

In addition to the structure represented by Formula (1-a) or Formula (1-b), a structure which may be included in the siloxane polymer (A) is not particularly limited as long as the structure has a siloxane bond, and may include a structure known in the related art.

The siloxane polymer (A) having the structure represented by Formula (1-a) or Formula (1-b) is obtained by polycondensating the corresponding alkoxysilane compound. For example, the siloxane polymer (A) is obtained by a sol-gel method.

The weight average molecular weight of the siloxane polymer (A) of the present invention is preferably in a range of 1,000 to 100,000, more preferably 1,200 to 50,000, and still more preferably 2,000 to 30,000 as a value in terms of polystyrene measured by a GPC method. By adjusting the weight average molecular weight to 1,000 to 100,000, solubility in a solvent may be compatible with improvement in film-formation property.

A siloxane polymer having a dispersion degree (molecular weight distribution) in a range of usually 1.1 to 3.0, and preferably 1.2 to 2.0 is used. The smaller the molecular weight distribution is, the better the mobility of charge (hole/electron) transport is.

The siloxane polymer (A) of the present invention may be (A-1) a siloxane polymer or (A-2) a siloxane polymer as described below.

[1-1] Siloxane Polymer (A-1)

The siloxane polymer (A-1) is a siloxane polymer having a repeating unit represented by the following Formula (2-1).

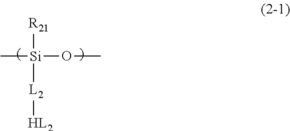

(In Formula (2-1), R₂₁ represents an alkyl group or an aryl group, L₂ represents a divalent linking group having 3 or more carbon atoms, and HL₂ represents a group including 2 or more triarylamine units.)

In Formula (2-1), R₂₁ represents an alkyl group or an aryl group.

The alkyl group is preferably an alkyl group having 1 to 8 carbon atoms and more preferably an alkyl group having 1 to 6 carbon atoms, and specifically, a methyl group, an ethyl group and a t-butyl group are preferred, a methyl group and an ethyl group are more preferred, and a methyl group is still more preferred.

The aryl group is an aryl group having preferably 6 to 20 carbon atoms, and more preferably 6 to 12 carbon atoms, and specific examples thereof include a phenyl group, a naphthyl group, a biphenyl group, an anthryl group and the like, and a phenyl group and a naphthyl group are preferred.

R₂₁ is preferably an alkyl group in view of improving solvent solubility and film-formation property.

In Formula (2-1), HL₂ represents a group (also referred to as a pendant group) including 2 or more triarylamine units.

It is thought that the amorphous property of the siloxane polymer (A-1) is increased by having a pendant group including a triarylamine unit having high crystallinity at the side chain of the siloxane main chain, thereby improving the film-formation property.

HL₂ is preferably represented by the following Formula (2-2).

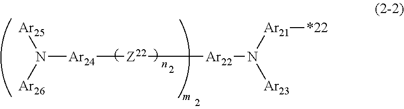

(In Formula (2-2), each of Ar₂₁, Ar₂₂ and Ar₂₄ independently represents an arylene group, and each of Ar₂₃, Ar₂₅ and Ar₂₆ independently represents an aryl group. Z²² represents a divalent linking group. Each of Ar₂₄, Ar₂₅, Ar₂₆ and Z²², if present in plurality, may be the same as or different from every other Ar₂₄, Ar₂₅, Ar₂₆ and Z²². n₂ represents the number of Z²²'s in each triarylamine unit, and n₂ represents 0 or 1. m₂ represents the repeating number of the triarylamine unit, and m₂ represents an integer of 1 or more. When m₂ is 2 or more, each of the triarylamine units are bonded to Ar₂₅ of one triarylamine unit and Z²² of the other triarylamine unit. When n₂=0 and m₂=1, Ar₂₂ is bonded to Ar₂₄ through a single bond, and when n₂=0 and m₂=2 or more, Ar₂₂ is bonded to Ar₂₄ through a single bond. In each of the triarylamine units, Ar₂₄ of one triarylamine unit is bonded to Ar₂₅ of the other triarylamine unit through a single bond. *22 represents a moiety bonded to L₂ in Formula (2-1).)

In Formula (2-2), each of Ar₂₁, Ar₂₂ and Ar₂₄ independently represents an arylene group. The arylene group is an arylene group having preferably 6 to 20 carbon atoms, and more preferably 6 to 12, and examples thereof include a phenylene group, a naphthylene group, a biphenylene group, a fluorenylene group, a phenanthrylene group, a pyrenylene group, a triphenylenylene group and the like. Due to improvement of the pendant group introduction rate and charge transporting property, preferred examples thereof include a phenylene group, a naphthylene group, a biphenylene group, a fluorenylene group, a phenanthrylene group and the like, and a phenylene group and a naphthylene group are most preferred.

In Formula (2-2), each of Ar₂₃, Ar₂₅ and Ar₂₆ independently represents an aryl group. The aryl group is an aryl group having preferably 6 to 20 carbon atoms, and more preferably 6 to 12, and examples thereof include a phenyl group, a naphthyl group, a biphenyl group, an anthryl group, a fluorenyl group, a phenanthryl group, a pyrenyl group, a triphenylenyl group and the like. Due to improvement of the pendant group introduction rate and charge transporting property, preferred examples thereof include a phenyl group, a naphthyl group, a biphenyl group, a fluorenyl group, a phenanthryl group and the like, and a phenyl group and a naphthyl group are most preferred.

In Formula (2-2), an arylene group or an aryl group represented by Ar₂₁ to Ar₂₆ may have a non-polymerizable substituent. Preferred examples of the substituent include an alkyl group (preferably an alkyl group having 1 to 8 carbon atoms, more preferably an alkyl group having 1 to 6 carbon atoms, and still more preferably a methyl group, an ethyl group and a t-butyl group), a silyl group (preferably a silyl group substituted with an alkyl group having 1 to 10 carbon atoms, and more preferably a trimethylsilyl group), a halogen atom (preferably a fluorine atom), a cyano group, a cycloalkyl group (preferably a cyclohexyl group), an alkoxy group (preferably having 1 to 20 carbon atoms, and particularly preferred examples thereof include a methoxy group and an ethoxy group) and the like.

It is preferred that in Formula (2-2), Ar₂₁, Ar₂₂ and Ar₂₄ are a phenylene group, and Ar₂₃, Ar₂₅ and Ar₂₆ represent a phenyl group or a naphthyl group.

In Formula (2-2), Z²² represents a divalent linking group. As the divalent linking group, an alkylene group, a cycloalkylene group and a silylene group are preferred. The divalent linking group may have a substituent, and the substituent is the same as a substituent that an arylene group or an aryl group represented by Ar¹ to Ar⁶ may have.

The alkylene group represented by Z²² is preferably an alkylene group having 1 to 10 carbon atoms, specific examples thereof include a methylene group, an ethylene group, a propylene group, a butylene group, a pentylene group, a dimethylmethylene group, a diethylmethylene group, a diphenylmethylene group and the like, and preferred examples thereof include a dimethylmethylene group, a diethylmethylene group and a diphenylmethylene group.

The cycloalkylene group represented by Z²² is preferably a cycloalkylene group having 1 to 10 carbon atoms, specific examples thereof include a cyclopropylene group, a cyclobutylene group, a cyclopentylene group, a cyclohexylene group, a cycloheptylene group and the like, and preferred examples thereof include a cyclopentylene group, a cyclohexylene group and a cycloheptylene group.

The silylene group represented by Z²² is preferably a silylene group which is substituted with an alkyl group having 1 to 10 carbon atoms or an aryl group having 6 to 10 carbon atoms, more preferably a dimethylsilylene group, a diethylsilylene group and a diphenylsilylene group, and still more preferably a diphenylsilylene group.

In Formula (2-2), n₂ represents 0 or 1. When n₂ is 0, Ar₂₂ is bonded to Ar₂₄ through a single bond. In view of the fact that the conjugated system is expanded, and thus the charge transporting property is improved, n₂ is preferably 0.

In Formula (2-2), m₂ represents an integer of 1 or more. m₂ represents the repeating number of the triarylamine unit, and when m₂ is 2 or more, the triarylamine units are bonded to each other through Ar₂₅ and Z²². From the viewpoint of allowing the charge transporting property to be compatible with the solubility in a solvent, m₂ is preferably an integer of 1 to 9, more preferably an integer of 1 to 5, and still more preferably an integer of 1 to 3.

When n₂=0 and m₂=1, Ar₂₂ is bonded to Ar₂₄ through a single bond, and when n₂=0 and m₂ is 2 or more, Ar₂₂ and Ar₂₄ are bonded to Ar₂₄ and Ar₂₅, respectively, through a single bond.

When m₂ is 2 or more, each Z² may be the same as or different from every other Z².

It is preferred that Formula (2-2) is represented by any one of the following Formulas (2-5) to (2-7).

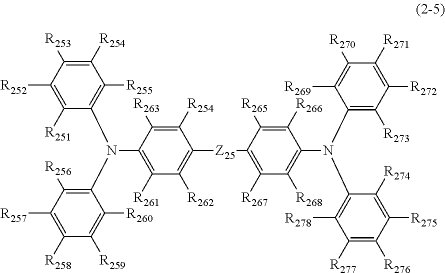

(In Formula (2-5), each of R₂₅₁ to R₂₇₈ independently represents a hydrogen atom, an alkyl group, a cycloalkyl group, an alkoxy group and a silyl group. However, one of R₂₅₁ to R₂₅₅ is bonded to L₂ in Formula (2-1). Z₂₅ represents a single bond or a divalent linking group.)

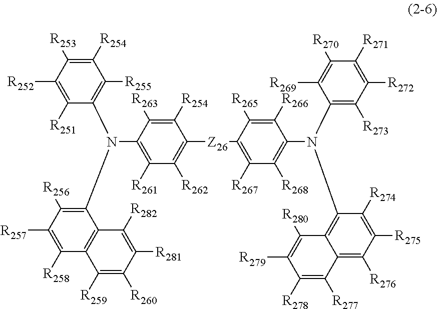

(In Formula (2-6), each of R₂₅₁ to R₂₈₂ independently represents a hydrogen atom, an alkyl group, a cycloalkyl group, an alkoxy group and a silyl group. However, one of R₂₅₁ to R₂₅₅ is bonded to L₂ in Formula (2-1). Z₂₆ represents a single bond or a divalent linking group.)

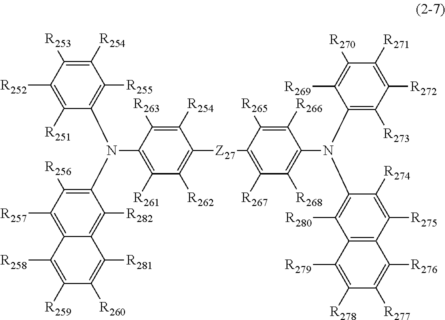

(In Formula (2-7), each of R₂₅₁ to R₂₈₂ independently represents a hydrogen atom, an alkyl group, a cycloalkyl group, an alkoxy group and a silyl group. However, one of R₂₅₁ to R₂₅₅ is bonded to L₂ in Formula (2-1). Z₂₇ represents a single bond or a divalent linking group.)

In Formulas (2-5) to (2-7), R₂₅₁ to R₂₈₂ represent a hydrogen atom, an alkyl group, a cycloalkyl group, an alkoxy group or a silyl group.

The alkyl group is preferably an alkyl group having 1 to 10 carbon atoms and more preferably an alkyl group having 1 to 6 carbon atoms, and still more preferably a methyl group, an ethyl group and a t-butyl group.

The cycloalkyl group is preferably a cycloalkyl group having 3 to 10 carbon atoms, and more preferably a cyclohexyl group and a cycloheptyl group.

The alkoxy group is preferably an alkoxy group having 1 to 10 carbon atoms, and more preferably a methoxy group and an ethoxy group.

The silyl group is preferably a silyl group substituted with an alkyl group having 1 to 10 carbon atoms, and more preferably a trimethylsilyl group.

In Formulas (2-5) to (2-7), R₂₅₁ to R₂₈₂ are preferably a hydrogen atom or an alkyl group, and more preferably a hydrogen atom.

In Formulas (2-5) to (2-7), Z₂₅ to Z₂₇ represent a single bond or a divalent linking group. Specific examples and preferred ranges of the divalent linking group are the same as those of the Z²². Z₂₅ to Z₂₇ are preferably a single bond, an alkylene group, a cycloalkylene group or a silylene group, and more preferably a single bond or a diphenylsilylene group.

In Formulas (2-5) to (2-7), one of R₂₅₁ to R₂₅₅ is bonded to L₂ in Formula (2-1).

In Formula (2-1), L₂ represents a divalent linking group having 3 or more carbon atoms. “A divalent linking group having 3 or more carbon atoms” refers to a divalent linking group having 3 or more carbon atoms in the main structure of the liking group. “The main structure of the linking group” refers to an atom or an atomic group used only for linking HL₂ in Formula (2-1) to a silicon atom, and particularly, refers to an atom or an atomic group constituting a path having the smallest number of atoms used when there is a plurality of linking paths.

The number of carbons included in L₂ is 3 or more. When the number of carbons in L₂ is less than 3, the linking group becomes rigid and the flexibility of the side chain deteriorates, and thus the film quality of a film obtained by film-forming the siloxane polymer (A-1) deteriorates. Further, when the number of carbons in L₂ is less than 3, the solubility of the siloxane polymer (A-1) in a solvent is reduced.

L₂ is a moiety having an insulating property, and thus in consideration of the charge transporting property of the siloxane polymer (A-1), the number of carbons in L₂ is preferably 3 to 12, more preferably 3 to 10, and still more preferably 3 to 7.

Further, it was possible to obtain an unexpected effect that the driving voltage in the characteristic of an organic EL device is significantly reduced by using the siloxane polymer (A-1) in the present invention. This is assumed because, by linking a pendant group having a triarylamine unit to a silicon atom in the siloxane main chain through a linker having 3 or more carbon atoms, a rigid arylamine unit is allowed to be pendant through the flexible linker, and thus the repetition of the arylamine unit is increased, thereby increasing the hole mobility.

The divalent linking group represented by L2 is preferably a divalent hydrocarbon group which may include an oxygen atom, a sulfur atom or a nitrogen atom, and more preferably an alkylene group, a cycloalkylene group, an arylene group, and a divalent group obtained by combination thereof, which may include an oxygen atom, a sulfur atom or a nitrogen atom.

L₂ is more preferably represented by the following Formula (2-3).

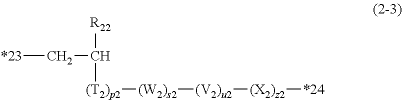

(In Formula (2-3), R₂₂ represents a hydrogen atom or an alkyl group, T₂ represents a divalent linking group, W₂ represents an oxygen atom, —NH— or a sulfur atom, V₂ represents a divalent linking group, and X₂ represents —CH₂—, an oxygen atom or —NH—. p₂ represents an integer of 1 to 5, s₂ represents 0 or 1, u₂ represents an integer of 0 to 5, and Z₂ represents 0 or 1. Each of T₂ and V₂, if present in plurality, may be the same as or different from every other T₂ and V₂. However, one of T₂, V₂ and X₂ includes at least one carbon atom. *23 represents a moiety bonded to a silicon atom in Formula (2-1), and *24 represents a moiety bonded to HL₂ in Formula (2-1).)

In Formula (2-3), R₂₂ represents a hydrogen atom or an alkyl group. The alkyl group is preferably an alkyl group having 1 to 8 carbon atoms, and more preferably an alkyl group having 1 to 6 carbon atoms, and specifically, a methyl group, an ethyl group and a t-butyl group are preferred, and a methyl group is more preferred, in view of solvent solubility and charge transporting property.

R₂₂ is particularly preferably a hydrogen atom or a methyl group.

In Formula (2-3), T₂ represents a divalent linking group. The divalent linking group is preferably a divalent hydrocarbon group, and more preferably an alkylene group, a cycloalkylene group, an arylene group and a divalent group obtained by combination thereof.

The alkylene group represented by T₂ is preferably an alkylene group having 1 to 10 carbon atoms, specific examples thereof include a methylene group, an ethylene group, a propylene group, a butylene group, a pentylene group, an octylene group and the like, and in view of solvent solubility and charge transporting property, specific examples thereof include a methylene group, an ethylene group, a propylene group, a butylene group, a pentylene group and a hexylene group.

In addition, the alkylene group may include a cycloalkylene group or an arylene group, and examples of the cycloalkylene group or the arylene group include a cycloalkylene group or an arylene group represented by T₂ as described below.

Specific examples of the cycloalkylene group represented by T₂ include a cyclopropylene group, a cyclobutylene group, a cyclopentylene group, a cyclohexylene group and a cycloheptylene group, and preferred examples thereof include a cyclohexylene group.

Specific examples of the arylene group represented by T₂ include a phenylene group, a naphthylene group, a biphenylene group, a fluorenylene group, a phenanthrylene group, a pyrenylene group, a triphenylenylene group and the like, and preferred examples thereof include a phenylene group, a napthylene group and a biphenylene group.

T₂ is preferably an alkylene group.

In Formula (2-3), W₂ represents an oxygen atom, —NH— or a sulfur atom. In view of chemical stability, W₂₂ is preferably an oxygen atom.

In Formula (2-3), V₂ represents a divalent linking group. Specific examples and preferred ranges of V₂ are the same as those of the T₂.

In Formula (2-3), X₂ represents —CH₂—, an oxygen atom or —NH—. In view of chemical stability, X₂ is preferably an oxygen atom.

In Formula (2-3), p₂ represents an integer of 1 to 5, s₂ represents 0 or 1, u₂ represents an integer of 0 to 5, and Z₂ represents 0 or 1. When s₂ is 0, T₂ is bonded to V₂ through a single bond. When u₂ is 0, W₂ is bonded to X₂ through a single bond. When Z₂ is 0, V₂ is directly bonded to HL₂ in Formula (2-1).

L₂ is more preferably represented by the following Formula (2-3-1).

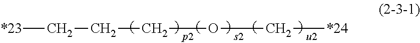

(In Formula (2-3-1), p₂ represents an integer of 1 to 5, s₂ represents 0 or 1, and u₂ represents an integer of 0 to 5. *23 represents a moiety bonded to a silicon atom in Formula (2-1), and *24 represents a moiety bonded to HL₂ in Formula (2-1).)

The sum of p₂, s₂ and u₂ is preferably 1 to 10, and more preferably 1 to 6.

The siloxane polymer (A-1) is preferably 10-mer to 50-mer of the repeating unit represented by Formula (2-1), and more preferably 30-mer to 50-mer. In the case of a 50-mer or more, the solubility in a solvent is reduced. When being a 10-mer or more, it is preferred in that the polymer does not cause solution mixing or swelling mixing when applied on an upper layer.

The siloxane polymer (A-1) may include a structural unit other than the structure represented by Formula (2-1). Examples of the structural unit which may be included include a —(SiR¹¹R¹²O)— unit and the like. Each of R¹¹ and R¹² independently represents an alkyl group (preferably a methyl group).

In the siloxane polymer (A-1), the content of the —(SiR¹¹R¹²O)— unit is preferably 80 mol % or less, and more preferably 50 mol % or less based on the total content of the structural unit represented by Formula (2-1), and it is still more preferred that the —(SiR¹¹R¹²O)— unit is not included.

Because there is possibility that the siloxane polymer (A-1) may become a site for trapping charges due to the reduction in chemical stability, or reaction with impurities, the ratio of the repeating unit including Si—H is preferably 0 mol % to 20 mol %, and more preferably 0 mol % to 10 mol %, based on the total amount of the repeating unit represented by Formula (2-1). Meanwhile, in the siloxane polymer (A-1) in the present invention, the repeating unit including Si—H represents an unreacted moiety in the synthesis of the siloxane polymer (A-1) as described below.

The mass average molecular weight (Mw) of the siloxane polymer (A-1) is preferably 10³ to 10⁵, and more preferably 10⁴ to 10′. The number average molecular weight (Mn) of the siloxane polymer (A-1) is preferably 10³ to 10⁵, and more preferably 10⁴ to 10⁵. Mw and Mn of the siloxane polymer (A-1) may be measured by GPC, and more specifically, the values are obtained by using a converted molecular weight calibration curve previously obtained from a constitutive curve of a standard monodisperse polystyrene using tetrahydrofuran as a solvent, and a polystyrene gel. As a GPC device, HLC-8220 GPC (manufactured by TOSOH Corporation) may be used.

The polydiversity (Mw/Mn) of the siloxane polymer (A-1) is preferably 1.0 to 3.0, and more preferably 1.0 to 2.0.

[Method of Synthesizing Siloxane Polymer (A-1)]

The siloxane polymer (A-1) may be obtained by hydrosilylation of a monomer having a moiety which becomes 2 or more arylamine units and a linking group having 3 or more carbon atoms with polyalkyl hydrosiloxane or polyaryl hydrosiloxane, such as polymethyl hydrosiloxane and the like.

The method of obtaining a siloxane monomer by using the hydrosilylation reaction is excellent in terms of the following points, compared to a method of obtaining a siloxane polymer by a dehydration condensation method by hydrolysis of chlorinated silane.

i) unreacted hydroxyl groups remain and the yield is increased.

ii) The molecular weight distribution of the siloxane polymer is narrow, and the reproducibility is also increased.

iii) A low molecular weight cyclic siloxane is not produced (in a synthesis method of simultaneously performing hydrolysis and dehydration condensation, the low molecular weight cyclic siloxane is produced (Experimental Chemistry Lecture 4th edition vol. 28), and the cyclic siloxane has high volatility, and thus it is assumed that the cyclic siloxane becomes vapor and is diffused out of an organic EL device during the manufacturing process of the device. Further, when time is elapsed, the cyclic siloxane breaks down to silicon dioxide, carbon dioxide and water, and thus there is much concern in that the device performance after the manufacturing deteriorates).

iv) An acid is not produced (hydrochloric acid is produced in the hydrolysis of chlorinated silane, and acts as an acidic catalyst, and thus polymerization proceed (Experimental Chemistry Lecture 4th edition vol. 28). There is concern of decomposition of the amine compound under acidic conditions).

Polyalkyl hydrosiloxane or polyaryl hydrosiloxane may be obtained by a generally known dehydration condensation method, and the molecular weight thereof may be adjusted by regulating the reaction time and the reaction temperature. Further, it is possible to end-cap the terminal moiety by trialkyl silanol. A component with a desired molecular weight may be obtained from the polyalkyl hydrosiloxane or polyaryl hydrosiloxane thus obtained with a narrow distribution by using aliquot GPC.

The monomer having a moiety which becomes 2 or more arylamine units and a linking group having 3 or more carbon atoms is preferably a compound represented by the following Formula (2-4).

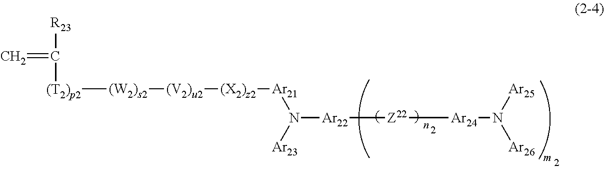

(In Formula (2-4), R₂₃ represents a hydrogen atom or an alkyl group, T₂ represents a divalent linking group, W₂ represents an oxygen atom, —NH— or a sulfur atom, V₂ represents a divalent linking group, and X₂ represents —CH₂—, an oxygen atom or —NH—. p₂ represents an integer of 1 to 5, s₂ represents 0 or 1, u₂ represents an integer of 0 to 5, and Z₂ represents 0 or 1. Each of T₂ and V₂, if present in plurality, may be the same as or different from every other T₂ and V₂. However, one of T₂, V₂ and X₂ includes at least one carbon atom. In Formula (2-4), each of Ar₂₁, Ar₂₂ and Ar₂₄ independently represents an arylene group, and each of Ar₂₃, Ar₂₅ and Ar₂₆ independently represents an aryl group. Z²² represents a divalent linking group. Each of Ar₂₄, Ar₂₅, Ar₂₆ and Z²², if present in plurality, may be the same as or different from every other Ar₂₄, Ar₂₅, Ar₂₆ and Z²². n₂ represents the number of Z²²'s in each triarylamine unit, and n₂ represents 0 or 1. m₂ represents the repeating number of the triarylamine unit, and m₂ represents an integer of 1 or more. When m₂ is 2 or more, the triarylamine units are each bonded to Ar₂₅ of one triarylamine unit and Z²² of the other triarylamine unit. When n₂=0 and m₂=1, Ar₂₂ is bonded to Ar₂₄ through a single bond, and when n₂=0 and m₂=2 or more, Ar₂₂ is bonded to Ar₂₄ through a single bond. In each of the triarylamine units, Ar₂₄ of one triarylamine unit is bonded to Ar₂₅ of the other triarylamine unit through a single bond.

In Formula (2-4), R₂₃, T₂, W₂, V₂, X₂, p₂, s₂, u₂ and z₂ are the same as R₂₂, T₂, W₂, V₂, X₂, p₂, s₂, u₂ and z₂ in Formula (2-3). Ar₂₁, Ar₂₂ and Ar₂₄ are the same as Ar₂₁, Ar₂₂ and Ar₂₄ in Formula (2-2). Ar₂₃, Ar₂₅ and Ar₂₆ are the same as Ar₂₃, Ar₂₅ and Ar₂₆ in Formula (2-2). Z²², n₂ and m₂ are the same as Z²², n₂ and m₂ in Formula (2-2).

Specific examples of a monomer compound represented by Formula (2-4) will be shown as follows, but the present invention is not limited thereto.

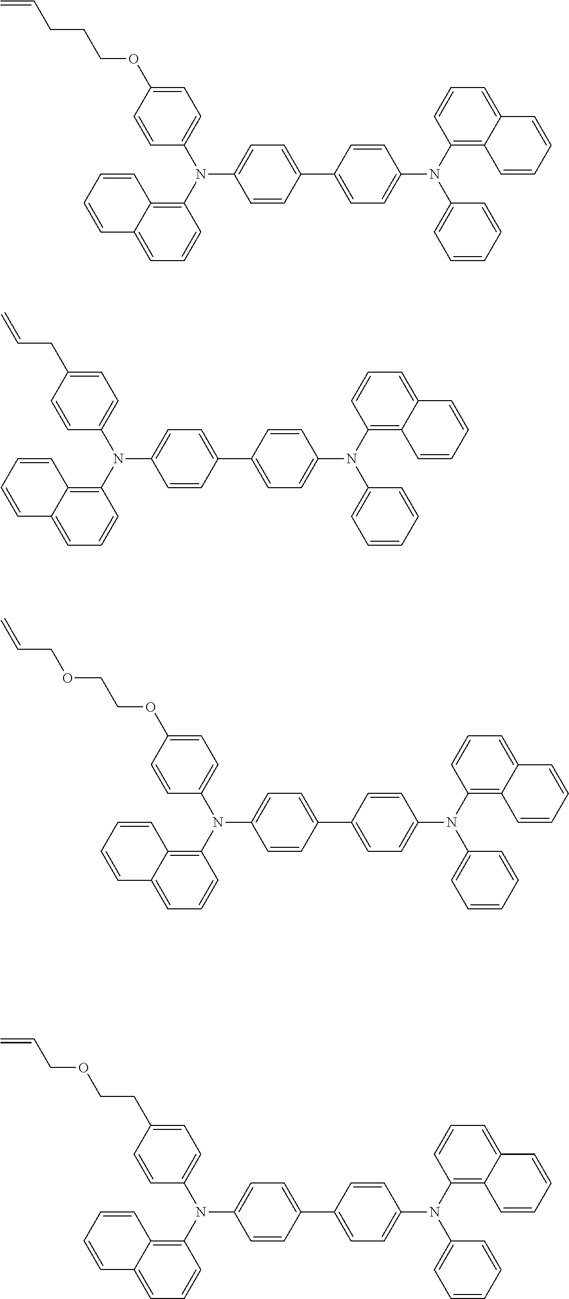 [SMILES: C=CCCCOc1ccc(N(c2ccc(-c3ccc(N(c4ccccc4)c4cccc5ccccc45)cc3)cc2)c2cccc3ccccc23)cc1 ; C=CCc1ccc(N(c2ccc(-c3ccc(N(c4ccccc4)c4cccc5ccccc45)cc3)cc2)c2cccc3ccccc23)cc1 ; C=CCOCCOc1ccc(N(c2ccc(-c3ccc(N(c4ccccc4)c4cccc5ccccc45)cc3)cc2)c2cccc3ccccc23)cc1 ; C=CCOCCc1ccc(N(c2ccc(-c3ccc(N(c4ccccc4)c4cccc5ccccc45)cc3)cc2)c2cccc3ccccc23)cc1]

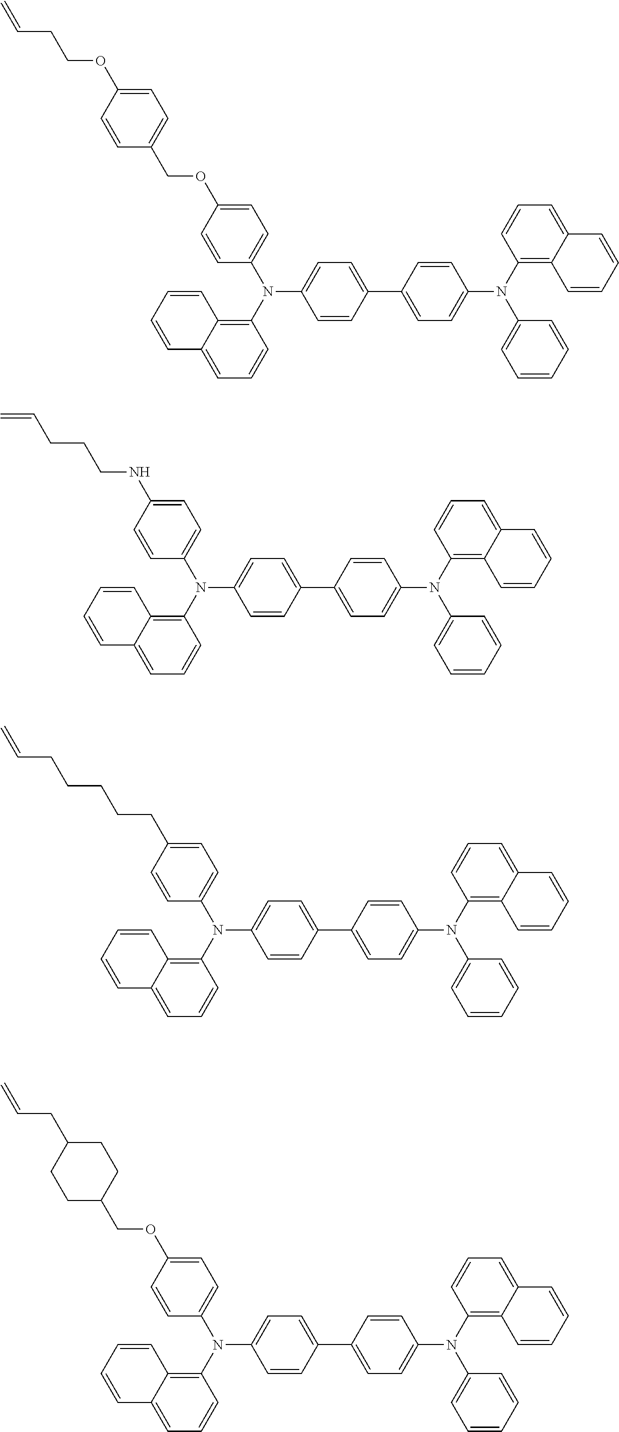 [SMILES: C=CCCOc1ccc(COc2ccc(N(c3ccc(-c4ccc(N(c5ccccc5)c5cccc6ccccc56)cc4)cc3)c3cccc4ccccc34)cc2)cc1 ; C=CCCCNc1ccc(N(c2ccc(-c3ccc(N(c4ccccc4)c4cccc5ccccc45)cc3)cc2)c2cccc3ccccc23)cc1 ; C=CCCCCCc1ccc(N(c2ccc(-c3ccc(N(c4ccccc4)c4cccc5ccccc45)cc3)cc2)c2cccc3ccccc23)cc1 ; C=CCC1CCC(COc2ccc(N(c3ccc(-c4ccc(N(c5ccccc5)c5cccc6ccccc56)cc4)cc3)c3cccc4ccccc34)cc2)CC1]

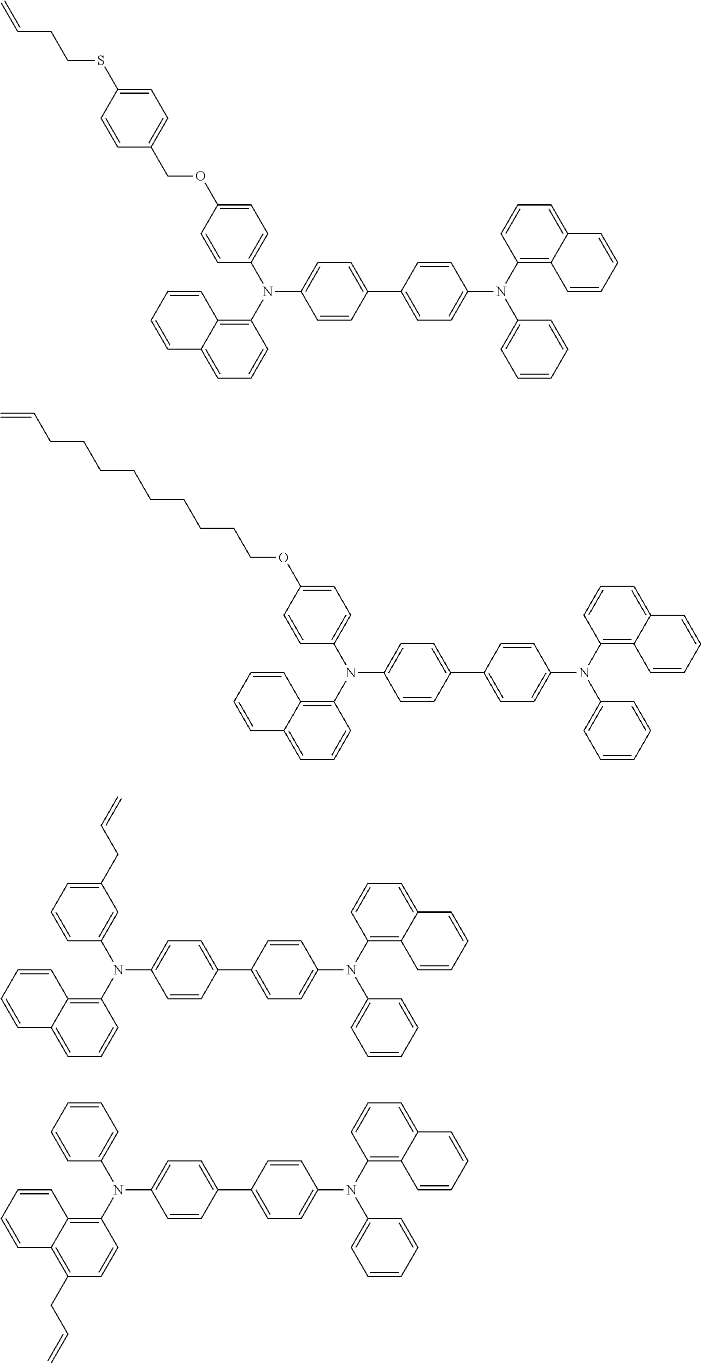

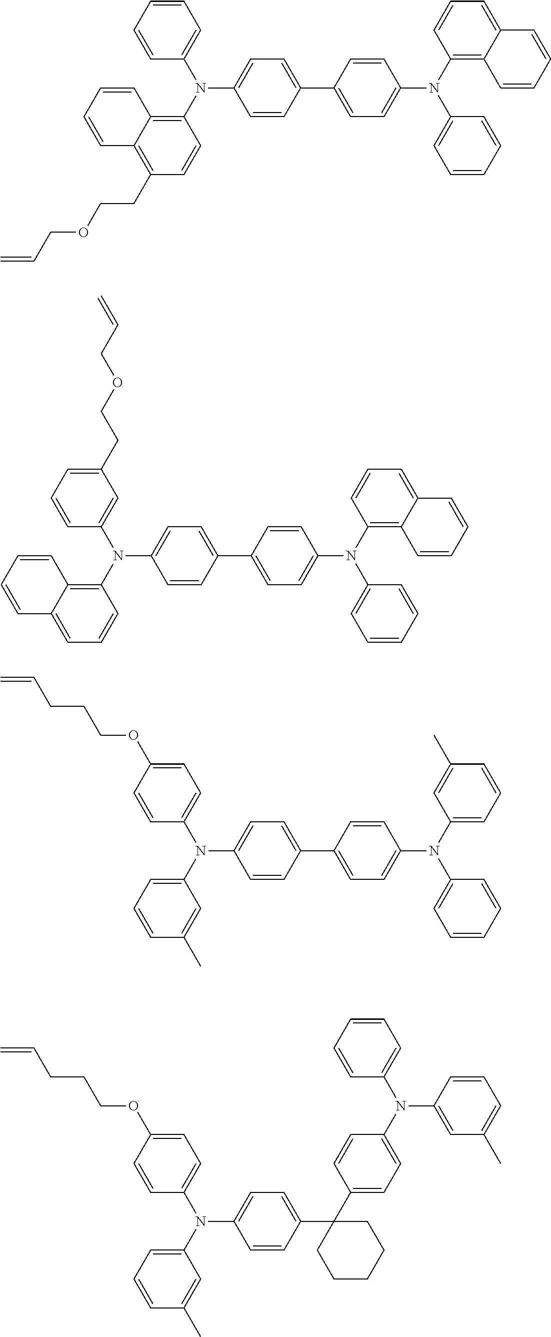 [SMILES: C=CCOCCc1ccc(N(c2ccccc2)c2ccc(-c3ccc(N(c4ccccc4)c4cccc5ccccc45)cc3)cc2)c2ccccc12 ; C=CCOCCc1cccc(N(c2ccc(-c3ccc(N(c4ccccc4)c4cccc5ccccc45)cc3)cc2)c2cccc3ccccc23)c1 ; C=CCCCOc1ccc(N(c2ccc(-c3ccc(N(c4ccccc4)c4cccc(C)c4)cc3)cc2)c2cccc(C)c2)cc1 ; C=CCCCOc1ccc(N(c2ccc(C3(c4ccc(N(c5ccccc5)c5cccc(C)c5)cc4)CCCCC3)cc2)c2cccc(C)c2)cc1]

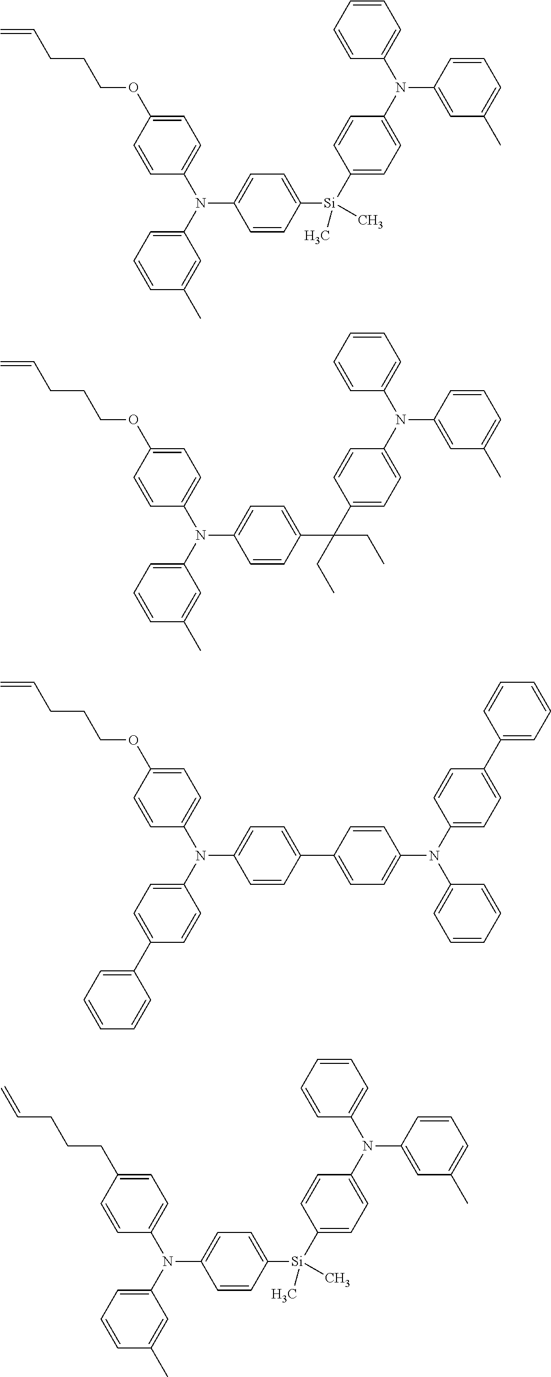

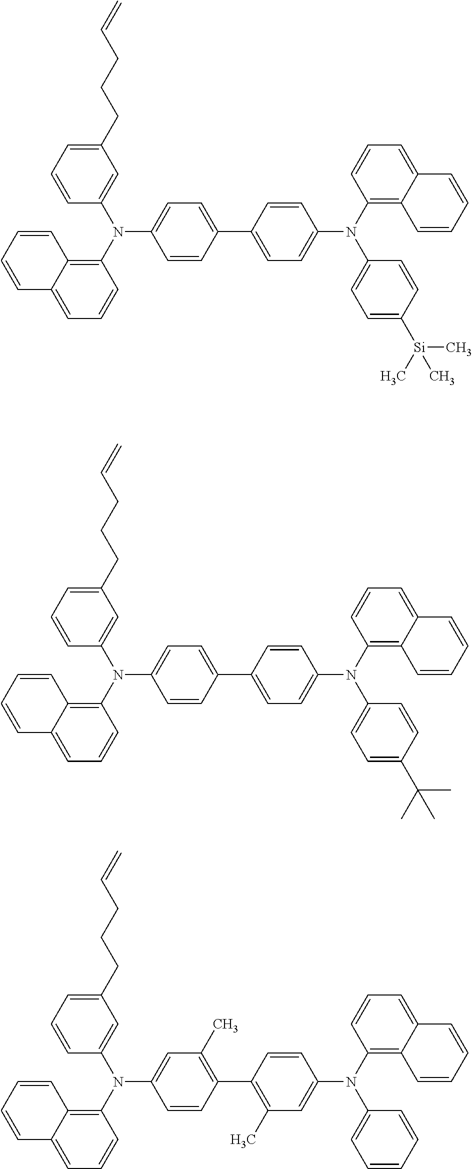 [SMILES: C=CCCCc1cccc(N(c2ccc(-c3ccc(N(c4ccc([Si](C)(C)C)cc4)c4cccc5ccccc45)cc3)cc2)c2cccc3ccccc23)c1 ; C=CCCCc1cccc(N(c2ccc(-c3ccc(N(c4ccc(C(C)(C)C)cc4)c4cccc5ccccc45)cc3)cc2)c2cccc3ccccc23)c1 ; C=CCCCc1cccc(N(c2ccc(-c3ccc(N(c4ccccc4)c4cccc5ccccc45)cc3C)c(C)c2)c2cccc3ccccc23)c1]

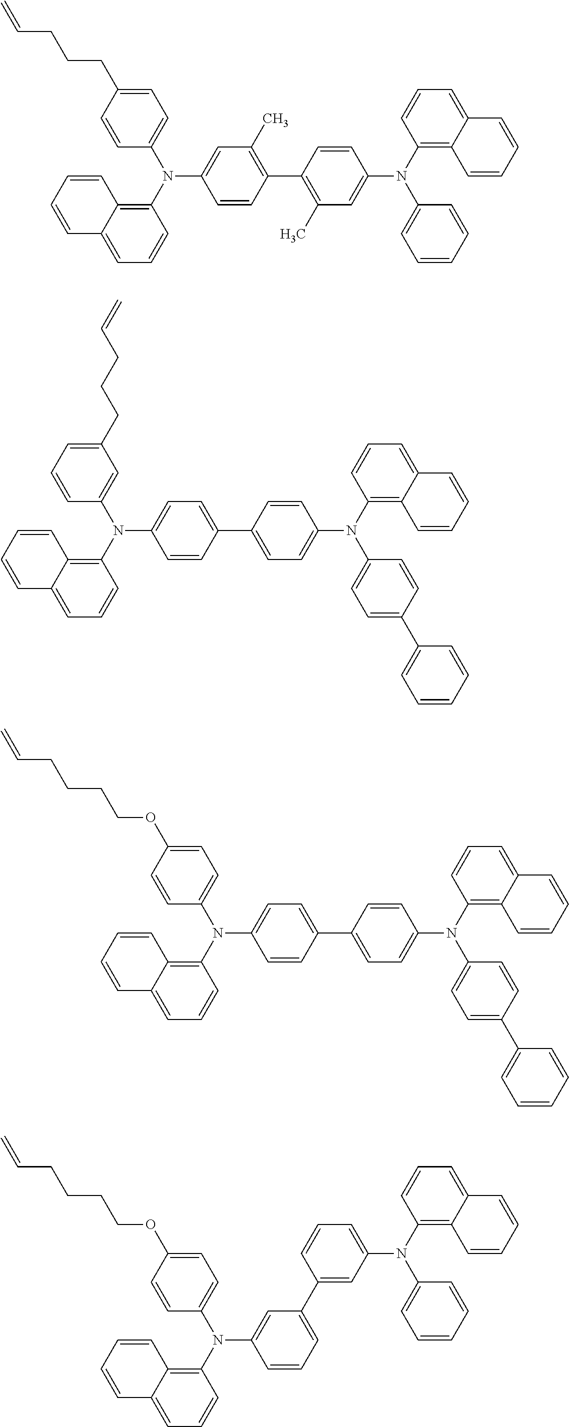

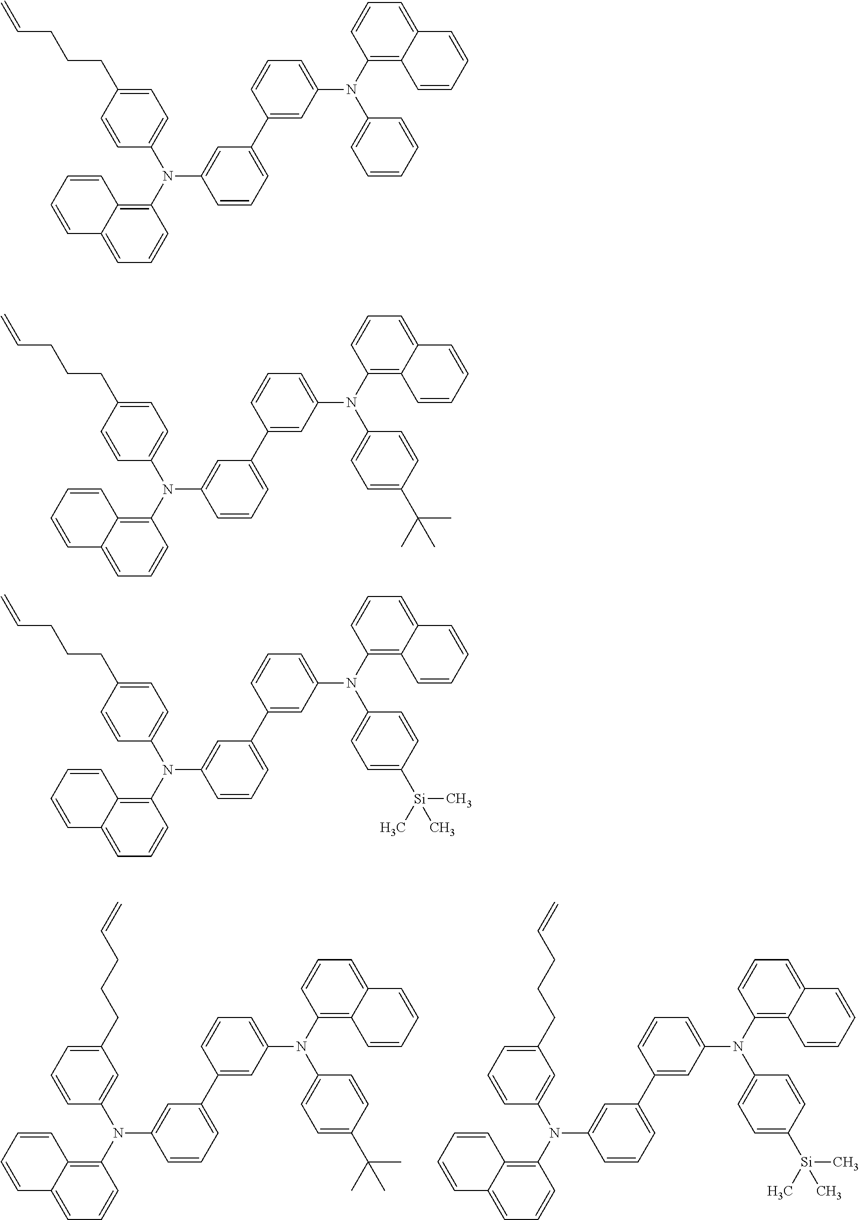

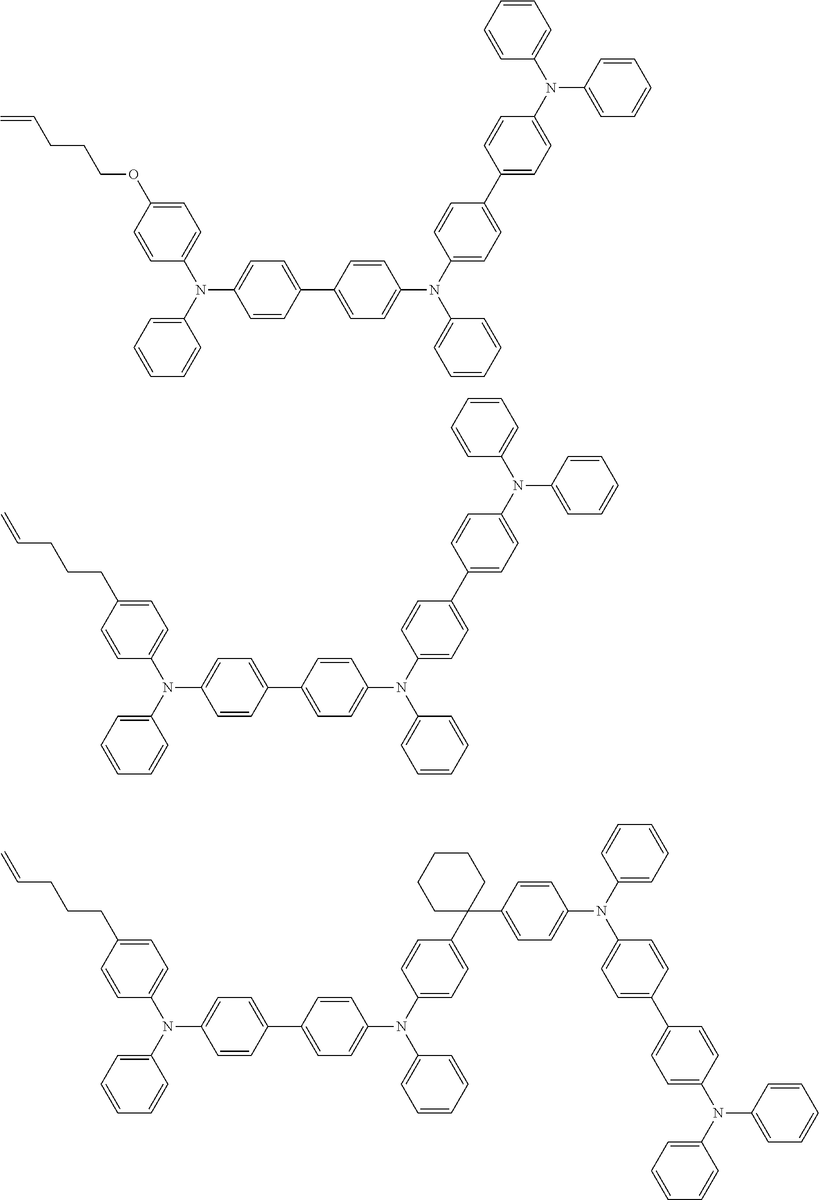

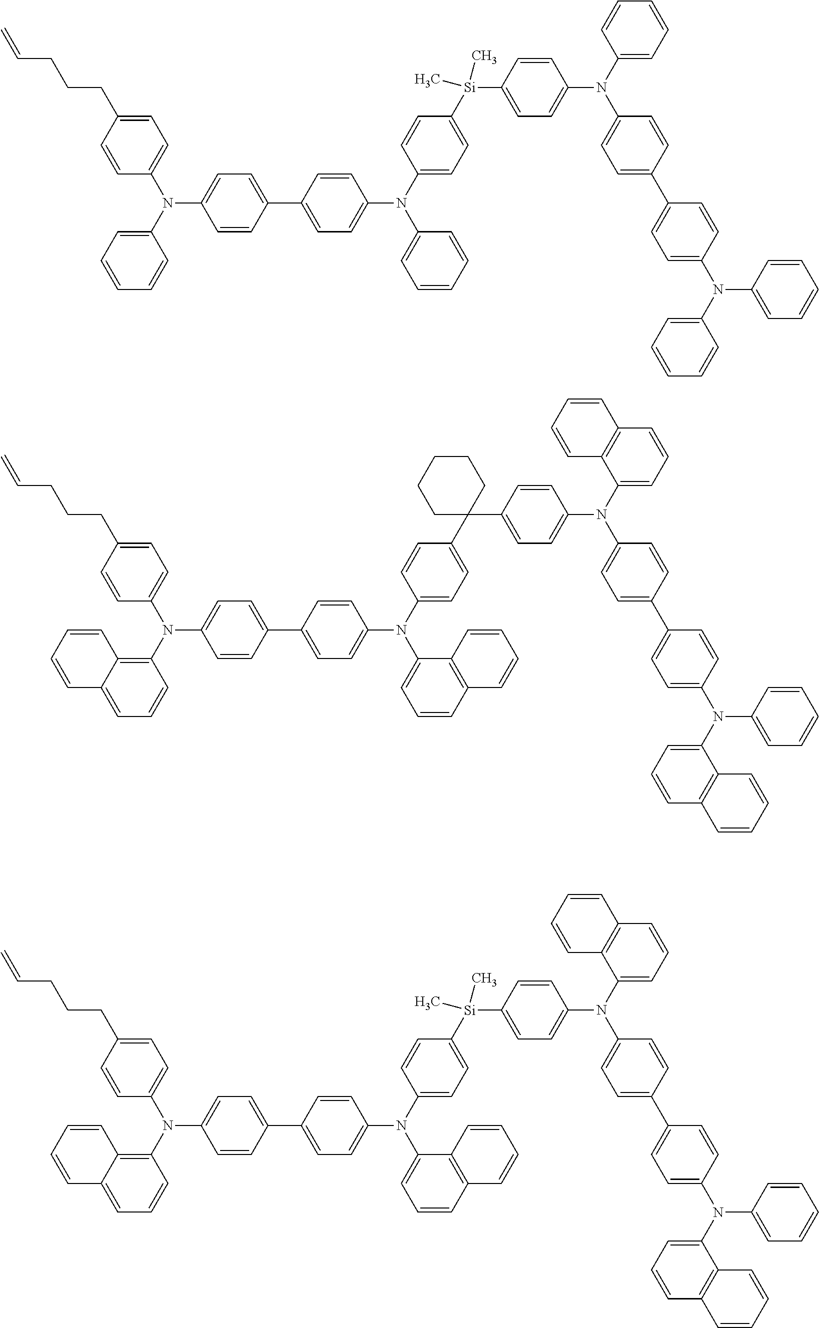 [SMILES: C=CCCCc1ccc(N(c2ccccc2)c2ccc(-c3ccc(N(c4ccccc4)c4ccc([Si](C)(C)c5ccc(N(c6ccccc6)c6ccc(-c7ccc(N(c8ccccc8)c8ccccc8)cc7)cc6)cc5)cc4)cc3)cc2)cc1 ; C=CCCCc1ccc(N(c2ccc(-c3ccc(N(c4ccc(C5(c6ccc(N(c7ccc(-c8ccc(N(c9ccccc9)c9cccc%10ccccc9%10)cc8)cc7)c7cccc8ccccc78)cc6)CCCCC5)cc4)c4cccc5ccccc45)cc3)cc2)c2cccc3ccccc23)cc1 ; C=CCCCc1ccc(N(c2ccc(-c3ccc(N(c4ccc([Si](C)(C)c5ccc(N(c6ccc(-c7ccc(N(c8ccccc8)c8cccc9ccccc89)cc7)cc6)c6cccc7ccccc67)cc5)cc4)c4cccc5ccccc45)cc3)cc2)c2cccc3ccccc23)cc1]

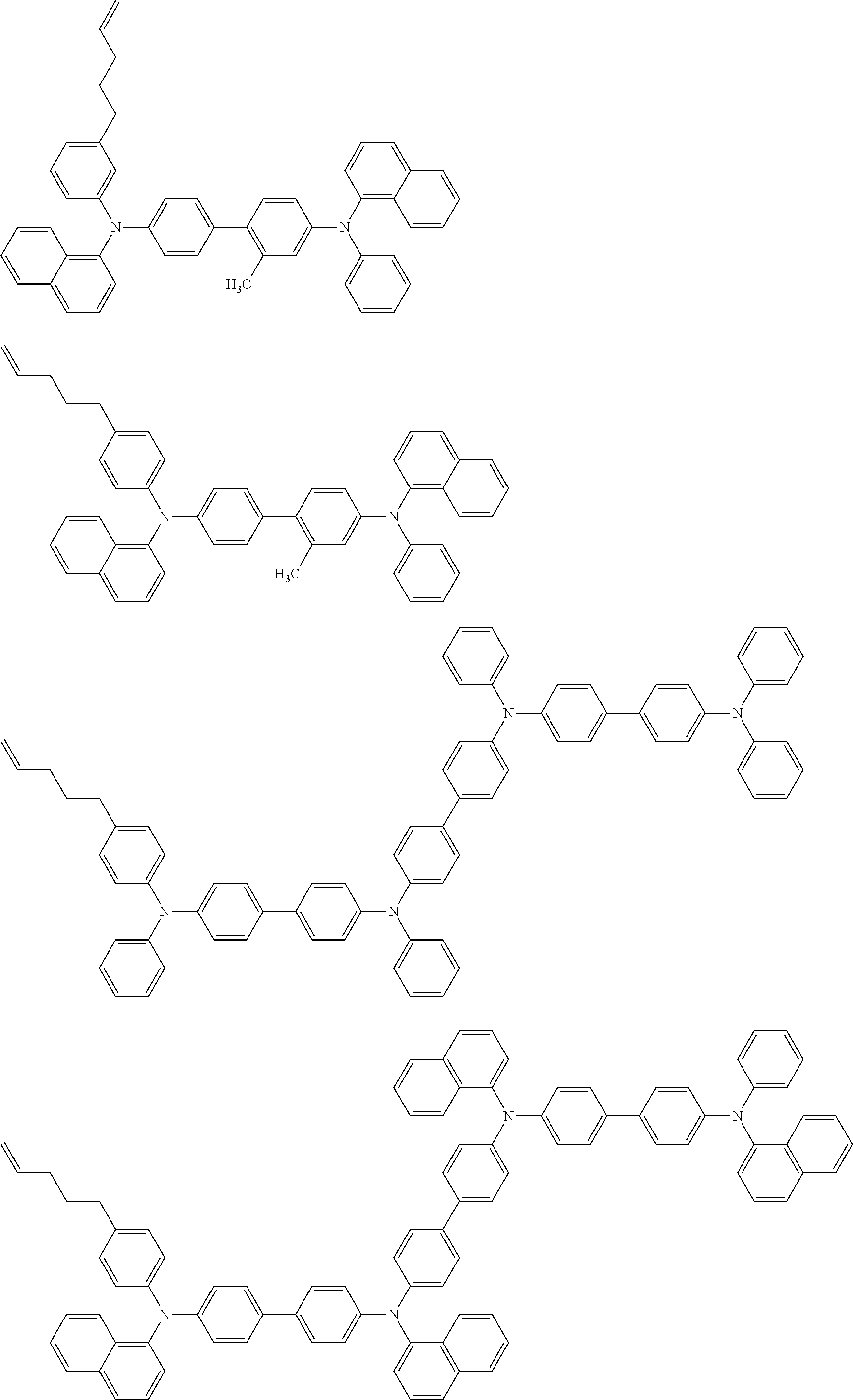

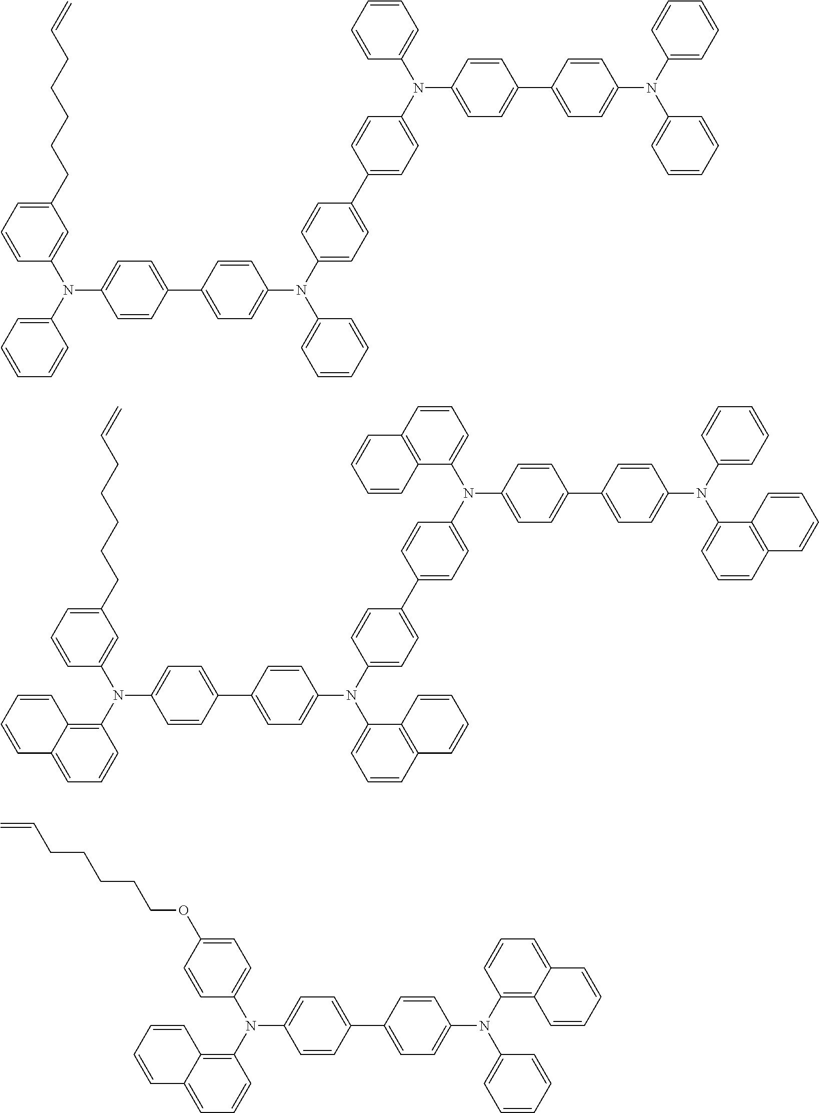 [SMILES: C=CCCCCCc1cccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)c1 ; C=CCCCCCc1cccc(N(c2ccc(-c3ccc(N(c4ccc(-c5ccc(N(c6ccc(-c7ccc(N(c8ccccc8)c8cccc9ccccc89)cc7)cc6)c6cccc7ccccc67)cc5)cc4)c4cccc5ccccc45)cc3)cc2)c2cccc3ccccc23)c1 ; C=CCCCCCOc1ccc(N(c2ccc(-c3ccc(N(c4ccccc4)c4cccc5ccccc45)cc3)cc2)c2cccc3ccccc23)cc1]

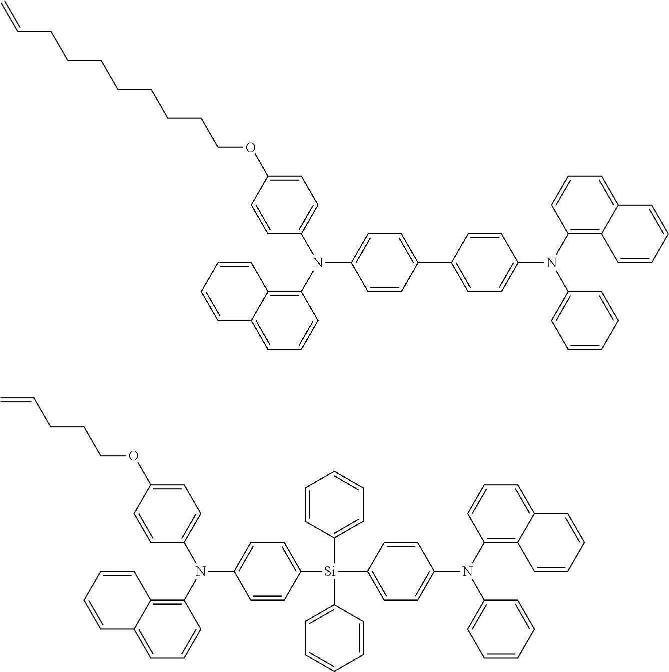 [SMILES: C=CCCCCCCCCOc1ccc(N(c2ccc(-c3ccc(N(c4ccccc4)c4cccc5ccccc45)cc3)cc2)c2cccc3ccccc23)cc1 ; C=CCCCOc1ccc(N(c2ccc([Si](c3ccccc3)(c3ccccc3)c3ccc(N(c4ccccc4)c4cccc5ccccc45)cc3)cc2)c2cccc3ccccc23)cc1]

The loading ratio (molar ratio) of each compound during the synthesis of the polymer siloxane (A-1) is preferably 1:1, and more preferably 0.9:1, because it is preferred that in the polycondensate obtained by dehydration-condensing the alkoxy silane and the monomer compound represented by Formula (2-4), the ratio of unreacted Si—H is decreased.

The reaction temperature in the synthesis is preferably 40° C. to 110° C., and more preferably 80° C. to 110° C., because reactivity and base material are in a reaction in the uniform system.

The reaction time is preferably 3 hours to 48 hours, and more preferably 8 hours to 48 hours. A catalyst in the reaction is preferably a dicyclopentadienyl platinum catalyst. As the solvent, toluene is preferred.

In addition, in the synthesis of the siloxane polymer (A-1), a polymerization initiator is not needed, and adverse effects are not caused by incorporation of the polymerization initiator in an organic electroluminescence device.

[1-2] Siloxane Polymer (A-2)

The siloxane polymer (A-2) has 2 or more triarylamine units as one pendant group, and has a structure in which the pendant group is linked to a silicon atom through a divalent linking group having 3 or more carbon atoms, and the pendant group is linked in an amount 0.1% to 10% thereof to 2 or more silicon atoms.

The pendant group possessed by the siloxane polymer (A-2) has 2 or more triarylamine units. Here, the pendant group represents not a group included in the main chain in the siloxane polymer (A-2), but a group included as a part of the side chain.

The triarylamine unit is a moiety having a structure in which three arylamine groups are substituted with nitrogen atoms, and one pendant group possessed by the siloxane polymer (A-2) has two or more of the units.

It is preferred that the siloxane polymer (A-2) in the present invention has a structure represented by the following Formula (3-a) and a structure represented by the following Formula (3-b).

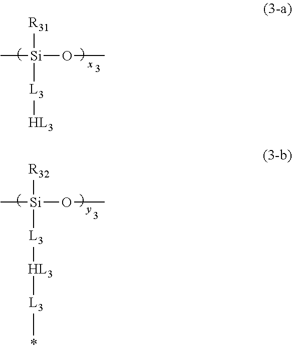

(In Formula (3-a) and Formula (3-b), each of R₃₁ and R₃₂ independently represents an alkyl group or an aryl group, each of L₃ independently represents a divalent linking group having 3 or more carbon atoms, and each of HL₃ independently represents a pendant group including 2 or more triarylamine units. x₃ and y₃ represent each of the number of siloxy moieties, x₃:y₃ is 99.9:0.1 to 90:10, and x₃+y₃ is 10 to 50. * represents a moiety bonded to a silicon atom of the siloxane polymer (A-2).)

In a siloxane polymer (A-2) (hereinafter also referred to as siloxane polymer (A-2-1)) having a structure represented by Formula (3-a) and a structure represented by Formula (3-b), the structure represented by Formula (3-a) and the structure represented by Formula (3-b) may be continuous, or may not be continuous. That is, the siloxane polymer (A-2-1) may be a random copolymer of the structure represented by Formula (3-a) and the structure represented by Formula (3-b), and a block copolymer thereof.

In Formula (3-a) and Formula (3-b), each of R₃₁ and R₃₂ independently represents an alkyl group or an aryl group.

The alkyl group is preferably an alkyl group having 1 to 8 carbon atoms and more preferably an alkyl group having 1 to 6 carbon atoms, and specifically, a methyl group, an ethyl group and a t-butyl group are preferred, and a methyl group is more preferred.

The aryl group is an aryl group having preferably 6 to 20 carbon atoms, and more preferably 6 to 12 carbon atoms, specific examples thereof include a phenyl group, a naphthyl group, a biphenyl group, an anthryl group and the like, and a phenyl group and a naphthyl group are preferred.

R₃₁ and R₃₂ are preferably an alkyl group.

In Formula (3-a) and Formula (3-b), each of HL₃ independently represents a pendant group including 2 or more triarylamine units. It is preferred that HL₃ is represented by the following Formula (3-2).

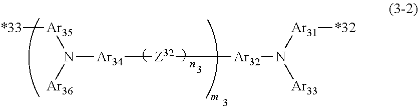

(In Formula (3-2), each of Ar₃₁, Ar₃₂, Ar₃₄ and A₃₅ independently represents an arylene group, and each of Ar₃₃ and Ar₃₆ independently represents an aryl group. Z³² represents a divalent linking group. Each of Ar₃₄, Ar₃₅, Ar₃₆ and Z³², if present in plurality, may be the same as or different from every other Ar₃₄, Ar₃₅, Ar₃₆ and Z³². n₃ represents the number of Z²'s in each triarylamine unit, and n₃ is 0 or 1. m₃ represents the repeating number of the triarylamine unit, and m₃ represents an integer of 1 or more. When m₃ is 2 or more, the triarylamine units are each bonded to Ar₃₅ of one triarylamine unit and Z³² of the other triarylamine unit. When n₃=0 and m₃=1, Ar₃₂ is bonded to Ar₃₄ through a single bond, and when n₃=0 and m₃=2 or more, Ar₃₂ is bonded to Ar₃₄ through a single bond. In each of the triarylamine units, Ar₃₄ of one triarylamine unit is bonded to Ar₃₅ of the other triarylamine unit through a single bond. *32 and *33 represent a moiety bonded to L₃ in Formula (3-a) or Formula (3-b), or a moiety bonded to a hydrogen atom.)

In Formula (3-2), each of Ar₃₁, Ar₃₂, Ar₃₄ and Ar₃₅ independently represents an arylene group. The arylene group is an arylene group having preferably 6 to 20 carbon atoms, and more preferably 6 to 12 carbon atoms, examples thereof include a phenylene group, a naphthylene group, an anthracenylene group, a biphenylene group, a terphenylene group, a fluorenylene group, a phenanthrylene group, a pyrenylene group, a triphenylenylene group and the like, and Ar₃₁ and Ar₃₅ are preferably a phenylene group and a naphthylene group, and Ar₃₂ and Ar₃₄ are a phenylene group, a fluorenylene group and an anthracenylene group, in view of the fact that the charge injection transporting property is increased by optimizing the ionization potential or increasing the repetition of an orbital between molecules.

In Formula (3-2), each of Ar₃₃ and Ar₃₆ independently represents an aryl group. The aryl group is an aryl group having preferably 6 to 20 carbon atoms, and more preferably an aryl group having 6 to 12 carbon atoms, specific examples thereof include a phenyl group, a naphthyl group, a biphenyl group, a terphenyl group, an anthracenyl group, a fluorenyl group, a phenanthryl group, a pyrenyl group, a triphenylenyl group and the like, and a phenyl group or a naphthyl group is preferred, in view of the fact that the charge injection transporting property is increased by optimizing the ionization potential or increasing the repetition of an orbital between molecules.

In Formula (3-2), an arylene group or an aryl group represented by Ar₃₁ to Ar₃₆ may have a substituent. Preferred examples of the substituent include an alkyl group (preferably an alkyl group having 1 to 8 carbon atoms, more preferably an alkyl group having 1 to 6 carbon atoms, and still more preferably a methyl group, an ethyl group and a t-butyl group), a silyl group (preferably a silyl group substituted with an alkyl group having 1 to 10 carbon atoms, and more preferably a trimethylsilyl group), a cyano group, an alkoxy group (preferably having 1 to 20 carbon atoms, and particularly preferred examples thereof include a methoxy group and an ethoxy group) and the like.

It is particularly preferred that in Formula (3-2), Ar₃₁, Ar₃₂, Ar₃₄ and Ar₃₅ are a phenylene group, and Ar₃₃ and Ar₃₆ represent a naphthyl group.

In Formula (3-2), Z³² represents a divalent linking group. As the divalent linking group, an alkylene group, a cycloalkylene group and a silylene group are preferred. The divalent linking group may have a substituent, and the substituent is the same as a substituent that an arylene group or an aryl group represented by Ar³¹ to Ar³⁶ may have.

The alkylene group represented by Z³² is preferably an alkylene group having 1 to 10 carbon atoms, specific examples thereof include a methylene group, an ethylene group, a propylene group, a butylene group, a pentylene group, a dimethylmethylene group, a diethylmethylene group and the like, and preferred examples thereof include a dimethylmethylene group and a diethylmethylene group.

The cycloalkylene group represented by Z³² is preferably a cycloalkylene group having 3 to 10 carbon atoms, specific examples thereof include a cyclopropylene group, a cyclobutylene group, a cyclopentylene group, a cyclohexylene group, a cycloheptylene group and the like, and preferred examples thereof include a cyclohexylene group.

The silylene group represented by Z³² is preferably a silylene group which is substituted with an alkyl group having 1 to 10 carbon atoms, and more preferably a dimethylsilylene group and a diethylsilylene group.

In Formula (3-2), n₃ represents 0 or 1. In order to control the ionization potential, n₃ may be appropriately selected between 0 and 1.

In Formula (3-2), m₃ represents an integer of 1 or more. m₃ represents the repeating number of the triarylamine unit, and when m₃ is 2 or more, triarylamine units are bonded to each other through Ar₃₅ and Z³². From the viewpoint of charge transporting property and ionization potential, m₃ may be appropriately selected. m₃ is preferably an integer of 1 to 9, more preferably an integer of 1 to 5, and still more preferably an integer of 1 to 3.

When n₃=0 and m₃=1, Ar₃₂ is bonded to Ar₃₄ through a single bond, and when n₃=0 and m₃ is 2 or more, Ar₃₂ and Ar₃₄ are bonded to Ar₃₄ and Ar₃₅, respectively, through a single bond.

When m₃ is 2 or more, each Z³² may be the same as or different from every other Z³².

In Formula (3-2), *32 and *33 represent a moiety bonded to L₃ in Formula (3-a) or Formula (3-b), or a moiety bonded to a hydrogen atom. When *32 represents a moiety bonded to a hydrogen atom, Ar₃₁ bonded to a hydrogen atom forms an aryl group together with the hydrogen atom. When *33 represents a moiety bonded to a hydrogen atom, Ar₃₅ bonded to a hydrogen atom forms an aryl group together with the hydrogen atom. The aryl group may have a substituent, and the substituent is the same as that described above.

In Formula (3-a) and Formula (3-b), each of L₃ independently represents a divalent linking group having 3 or more carbon atoms.

The number of carbons included in L₃ is 3 or more. Here, the number of carbons included in L₃ refers to the number of carbons included in the main structure of the linking group represented by L₃. “The main structure of the linking group” refers to an atom or an atomic group used only for linking the pendant group to a silicon atom in the siloxane compound in the present invention, and particularly, refers to an atom or an atomic group constituting a path having the smallest number of atoms used when there are a plurality of linking paths. When the number of carbons of the divalent linking group L₃ is less than 3, the group is sterically crowded, and thus there is a problem in that the side chain introduction rate is reduced. When the number of carbons is 12 or less, the ratio of insulating moieties is not extremely increased, and thus the charge transporting property of the siloxane compound may be enhanced, which is preferred. Considering these facts, the number of carbons of the divalent linking group L₃ is preferably 3 to 12.

Further, it is possible to obtain an unexpected effect that the driving voltage in the characteristic of an organic EL device is significantly reduced by using the siloxane polymer (A-2). This is assumed because by linking a pendant group having 2 or more triarylamine units to a silicon atom in the siloxane main chain through a linker having 3 or more carbon atoms, steric hindrance is relieved and the flexibility of the linker is increased, and thus the repetition of the arylamine unit is increased, thereby increasing the hole mobility.

The mass ratio of the insulating moiety to the charge transportable moiety included in the siloxane polymer (A-2) is preferably 5:95 to 35:65, and more preferably 10:90 to 25:75. Here, the insulating moiety refers to a moiety in which charge does not flow, and refers to a siloxane main chain or a linker moiety in the present invention. Further, the charge transportable moiety refers to a moiety in which charge flows, and refers to a triarylamine moiety in the present invention.

The divalent linking group L₃ is preferably a divalent hydrocarbon group which may include an oxygen atom, a sulfur atom or a nitrogen atom, and more preferably an alkylene group, a cycloalkylene group, an arylene group, and a divalent group obtained by combination thereof, which may include an oxygen atom, a sulfur atom or a nitrogen atom.

L₃ is more preferably represented by the following Formula (3-3).

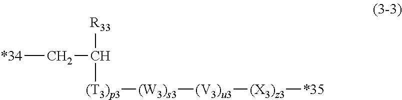

(In Formula (3-3), R₃₃ represents a hydrogen atom or an alkyl group, T₃ represents a divalent linking group, W₃ represents an oxygen atom, —NH— or a sulfur atom, V₃ represents a divalent linking group, and X₃ represents —CH₂—, an oxygen atom or —NH—. p₃ represents an integer of 1 to 5, s₃ represents 0 or 1, u₃ represents an integer of 0 to 5, and Z₃ represents 0 or 1. Each of T₃ and V₃, if present in plurality, may be the same as or different from every other T₃ and V₃. However, one of T₃, V₃ and X₃ includes at least one carbon atom. *34 represents a moiety bonded to a silicon atom in the main chain in Formula (3-a) or Formula (3-b), and *35 represents a moiety bonded to HL₃ in Formula (3-a) or Formula (3-b).)

In Formula (3-3), R₃₃ represents a hydrogen atom or an alkyl group. The alkyl group is preferably an alkyl group having 1 to 8 carbon atoms and more preferably an alkyl group having 1 to 6 carbon atoms, and specifically, a methyl group, an ethyl group and a t-butyl group are preferred, and a methyl group is more preferred, in view of reducing and suppressing the side chain introduction rate and reducing the crystallinity of the compound.

In Formula (3-3), T₃ represents a divalent linking group. The divalent linking group is preferably a divalent hydrocarbon group, and more preferably an alkylene group, a cycloalkylene group, an arylene group and a divalent group obtained by combination thereof.

The alkylene group represented by T₃ is preferably an alkylene group having 1 to 10 carbon atoms, specific examples thereof include a methylene group, an ethylene group, a propylene group, a butylene group, a pentylene group, an octylene group and the like, and in view of decreasing the insulating moiety or reducing the crystallinity of the compound, preferred examples thereof include a methylene group, an ethylene group, a propylene group, a butylene group and a pentylene group.

Further, the alkylene group may include a cycloalkylene group or an arylene group, and examples of the cycloalkylene group or the arylene group include a cycloalkylene group or an arylene group represented by T₃ as described below.

Specific examples of the cycloalkylene group represented by T₃ include a cyclopropylene group, a cyclobutylene group, a cyclopentylene group, a cyclohexylene group, a cycloheptylene group and the like, and preferred examples thereof include a cyclohexylene group.

Specific examples of the arylene group represented by T₃ include a phenylene group, a napthylene group, a bipheneylene group and the like, and preferred examples thereof include a phenylene group.

T₃ is preferably an alkylene group.

In Formula (3-3), W₃ represents an oxygen atom, —NH— or a sulfur atom. In view of reducing the crystallinity of the compound and enhancing the stability of the bond itself without leading to the charge trap, W₃ is preferably an oxygen atom.

In Formula (3-3), V₃ represents a divalent linking group. Specific examples and preferred ranges of V₃ are the same as those of the T₃.

In Formula (3-3), X₃ represents —CH₂—, an oxygen atom or —NH—. In view of not reducing charge resistance of the pendant group, X₃ is preferably —CH₂—.

In Formula (3-3), p₃ represents an integer of 1 to 5, s₃ represents 0 or 1, u₃ represents an integer of 0 to 5, and Z₃ represents 0 or 1. When s₃ is 0, T₃ is bonded to V₃ through a single bond. When u₃ is 0, W₃ is bonded to X₃ through a single bond. When z₃ is 0, V₃ is directly bonded to HL₃ in Formula (3-a) or Formula (3-b).

In view of the fact that reduction in the insulating moiety is compatible with reduction in the crystallinity of the compound, the sum of p₃, s₃, u₃ and z₃ is preferably 1 to 10, and more preferably 1 to 6.

L₃ is more preferably represented by the following Formula (3-3-1).

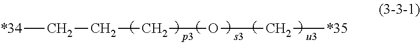

(In Formula (3-3-1), p₃ represents an integer of 1 to 5, s₃ represents 0 or 1, and u₃ represents an integer of 0 to 5. *34 represents a moiety bonded to a silicon atom in the main chain in Formula (3-a) or Formula (3-b), and *35 represents a moiety bonded to HL₃ in Formula (3-a) or Formula (3-b).)

The sum of p₃, s₃ and u₃ is preferably 1 to 10, and more preferably 1 to 6.

In Formula (3-3), *34 represents a moiety bonded to a silicon atom in the main chain in Formula (3-a) or Formula (3-b), and *35 represents a moiety bonded to HL₃ in Formula (3-a) or Formula (3-b).

In Formula (3-a) and Formula (3-b), each of x₃ and y₃ represents the number of structures represented by Formula (3-a) and a structure represented by Formula (3-b), x₃:y₃ is 99.9:0.1 to 90:10, and x₃+y₃ is 10 to 50.

By adjusting x₃/y₃ to 99.9/0.1 or less, it is difficult to cause solution mixing or swelling mixing when an upper layer is applied, and thus is preferred. Further, in a typical organic electroluminescence device, it is thought that the charge injection property is improved (the driving voltage is reduced) in a device in which a hole transporting layer and an upper layer thereof are mixed at the interface thereof, but in the present invention, it was possible to obtain an unexpectedly advantageous effect that light emission efficiency is improved and the driving voltage is reduced by suppressing the interface mixing in the present invention.

By adjusting x₃/y₃ to 90/10 or more, it is difficult to cause the deterioration in film quality, such as crack and the like to occur, which is preferred.

x₃:y₃ is preferably 99:1 to 90:10, and more preferably 97:3 to 92:8.

x₃+y₃ is preferably 10 to 45, more preferably 15 to 40, and particularly preferably 15 to 35, in view of solubility in a solvent and ease in controlling the purity of the compound.

x₃: y₃ may be controlled by adjusting the loading ratio of the monomer corresponding to each of Formula (3-a) and Formula (3-b).

Meanwhile, x₃ and y₃ refer to a value obtained by dividing the total number of a structure represented by Formula (3-a) and a structure represented by Formula (3-b) by the number of hydrosiloxanes in a polyhydrosiloxane compound as described below which is used during the synthesis of the siloxane polymer (A-2) of the present invention.

In Formula (3-b), * represents a moiety bonded to a silicon atom of the siloxane polymer (A-2). The silicon atom is preferably a silicon atom in the main chain other than the main chain included in Formula (3-a) and Formula (3-b), in view of solubility in a solvent and suppression of swelling by the solvent.

The siloxane polymer (A-2) may include a structural unit other than the structure represented by Formula (3-a) or Formula (3-b). Examples of the structural unit which may be included include a —(SiR¹¹R¹²O)— unit and the like. Each of R¹¹ and R¹² independently represents an alkyl group (preferably a methyl group).

In the siloxane polymer (A-2), the content of the —(SiR¹¹R¹²O)— unit is preferably 50% or less, and more preferably 25% or less based on the total number of the structural units represented by Formula (3-a) and the structural units represented by Formula (3-b), and it is still more preferred that the —(SiR¹¹R¹²O)— unit is not included.

The mass average molecular weight (Mw) of the siloxane polymer (A-2) is preferably 10,000 to 300,000, more preferably 20,000 to 200,000 and particularly preferably 50,000 to 150,000. The number average molecular weight (Mn) of the siloxane polymer (A-2) is preferably 5,000 to 300,000, more preferably 10,000 to 200,000 and particularly preferably 30,000 to 150,000. By adjusting the molecular weight in this range, it is possible to allow solubility in a solvent, when the siloxane compound is applied, to be compatible with solvent resistance when another layer is applied thereon. Mw and Mn of the siloxane polymer (A-2) may be measured with GPC, and more specifically, the values are obtained by using a converted molecular weight calibration curve previously obtained from a constitutive curve of a standard monodisperse polystyrene using THF (tetrahydrofuran) or N-methylpyrrolidone as a solvent, and a polystyrene gel. As a GPC device, HLC-8220 GPC (manufactured by TOSOH Corporation) may be used.

The polydiversity (Mw/Mn) of the siloxane polymer (A-2) is preferably 1 to 2, and more preferably 1 to 1.75.

[Method of Synthesizing Siloxane Polymer (A-2)]

The siloxane polymer (A-2) may be obtained by polymerization and crosslinking by hydrosilylation reaction, a monomer having a moiety which becomes 2 or more arylamine units and a linking group having 3 or more carbon atoms and becoming a pendant group bonded to one silicon atom and a monomer having a moiety which becomes 2 or more arylamine units and a linking group having 3 or more carbon atoms and becoming a pendant group bonded to two or more silicon atoms with polyalkyl hydrosiloxane or polyaryl hydrosiloxane, such as polymethyl hydrosiloxane and the like.

Polyalkyl hydrosiloxane or polyaryl hydrosiloxane may be obtained by a generally known dehydration condensation method, and the molecular weight thereof may be adjusted by regulating the reaction time and the reaction temperature. Further, it is possible to end-cap the terminal moiety by trialkyl silanol. A component with a desired molecular weight may be obtained from the polyalkyl hydrosiloxane or polyaryl hydrosiloxane thus obtained with a narrow distribution by using aliquot GPC.

Polyalkyl hydrosiloxane or polyaryl hydrosiloxane may be obtained by polycondensation of alkoxysilane or aryloxysilane. Examples of alkoxysilane or aryloxysilane include methyldimethoxyhydrosilane, ethyldimethoxyhydrosilane, phenyldimethoxyhydrosilane and the like. Among them, alkoxysilane is particularly preferred in view of reducing the ratio of the insulating moiety to reduce the crystallinity of the polysiloxane compound.

Examples of the monomer which becomes a pendant group bonded to one silicon atom include a compound having a polymerizable group (preferably an ethylenically unsaturated group) in a structure of the above-described pendant group, and preferred examples thereof include a compound having an ethylenically unsaturated group in a moiety which becomes the divalent linking group having 3 or more carbon atoms.

The monomer which becomes a pendant group bonded to one silicon atom is preferably represented by the following Formula (3-4).

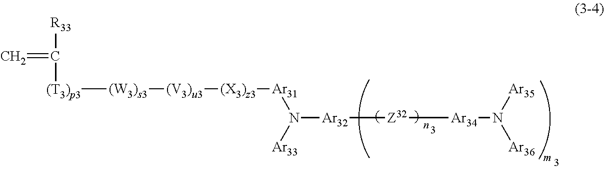

(In Formula (3-4), R₃₃ represents a hydrogen atom or an alkyl group, T₃ represents a divalent linking group, W₃ represents an oxygen atom, —NH— or a sulfur atom, V₃ represents a divalent linking group, and X₃ represents —CH₂—, an oxygen atom or —NH—. p₃ represents an integer of 1 to 5, s₃ represents 0 or 1, u₃ represents an integer of 0 to 5, and z₃ represents 0 or 1. Each of T₃ and V₃, if present in plurality, may be the same as or different from every other T₃ and V₃. However, one of T₃, V₃ and X₃ includes at least one carbon atom. Each of Ar₃₁, Ar₃₂ and Ar₃₄ independently represents an arylene group, and each of Ar₃₃, Ar₃₅ and Ar₃₆ independently represents an aryl group. Z³² represents a divalent linking group. Each of Ar₃₄, Ar₃₅, Ar₃₆ and Z³², if present in plurality, may be the same as or different from every other Ar₃₄, Ar₃₅, Ar₃₆ and Z³². n₃ represents the number of Z³²'s in each triarylamine unit, and n₃ represents 0 or 1. m₃ represents the repeating number of the triarylamine unit, and m₃ represents an integer of 1 or more. When m₃ is 2 or more, the triarylamine units are each bonded to Ar₃₅ of one triarylamine unit and Z³² of the other triarylamine unit. When n₃=0 and m₃=1, Ar₃₂ is bonded to Ar₃₄ through a single bond, and when n₃=0 and m₃=2 or more, Ar₃₂ is bonded to Ar₃₄ through a single bond. In each of the triarylamine units, Ar₃₄ of one triarylamine unit is bonded to Ar₃₅ of the other triarylamine unit through a single bond.)

In Formula (3-4), R₃₃, T₃, W₃, V₃, X₃, p₃, s₃, u₃ and z₃ are the same as R₃₃, T₃, W₃, V₃, X₃, p₃, s₃, u₃ and z₃ in Formula (3-3). Ar₃₁, Ar₃₂, Ar₃₄ and Ar₃₅ are the same as Ar₃₁, Ar₃₂, Ar₃₄ and Ar₃₅ in Formula (3-2). Ar₃₃ and Ar₃₆ are the same as Ar₃₃ and Ar₃₆ in Formula (3-2). Z³², n₃ and m₃ are the same as Z³², n₃ and m₃ in Formula (3-2).

Specific examples of the monomer compounds represented by Formula (3-4) include specific examples of the monomer compounds represented by Formula (2-4), but the present invention is not limited thereto.

The monomer compound represented by Formula (3-4) may be synthesized by performing a coupling reaction of aryl halide and aryl amine using a Pd catalyst step-by-step to obtain an asymmetric structure. Here, the polymerizable reaction moiety may be introduced in the initial reaction process or in the last reaction process, but preferably in the last reaction process.

The reaction temperature is preferably 50° C. to 150° C., and more preferably 60° C. to 130° C.

The reaction time is preferably 1 hour to 3 days, and more preferably 2 hours to 1 day.

As the solvent, any one may be used as long as the solvent may be used in a Pd coupling reaction, but toluene, DME (1,2-dimethoxyethane), THF and DMI (1,3-dimethyl-2-imidazolidinone) are preferred.

In the siloxane polymer (A-2), examples of the monomer which becomes a pendant group bonded to two or more silicon atoms include a compound having 2 or more polymerizable groups (preferably ethylenically unsaturated groups) in a structure of the above-described pendant group, and preferred examples thereof include a compound having an ethylenically unsaturated group in a moiety which becomes the divalent linking group having 3 or more carbon atoms.

Hereinafter, the monomer which becomes a pendant group bonded to 2 silicon atoms will be described, but the same will apply to the monomer which becomes a pendant group bonded to 3 or more silicon atoms.

The monomer which becomes a pendant group bonded to 2 silicon atoms is preferably represented by the following Formula (3-5).

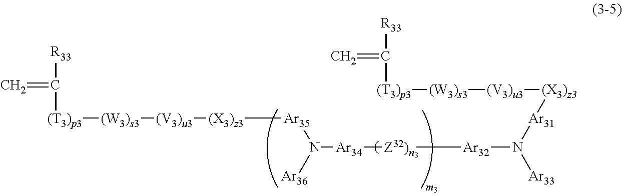

(In Formula (3-5), R₃₃ represents a hydrogen atom or an alkyl group, T₃ represents a divalent linking group, W₃ represents an oxygen atom, —NH— or a sulfur atom, V₃ represents a divalent linking group, and X₃ represents —CH₂—, an oxygen atom or —NH—. p₃ represents an integer of 1 to 5, s₃ represents 0 or 1, u₃ represents an integer of 0 to 5, and Z₃ represents 0 or 1. Each of Ar₃₁, Ar₃₂, Ar₃₄ and Ar₃₅ independently represents an arylene group, and each of Ar₃₃ and Ar₃₆ independently represents an aryl group. Z³² represents a divalent linking group. n₃ represents 0 or 1, and m3 represents an integer of 1 or more. When n₃=0 and m₃=1, Ar₃₂ is bonded to Ar₃₄ through a single bond, and when n₃=0 and m₃ is 2 or more, Ar₃₂ and Ar₃₄ are bonded to Ar₃₄ and Ar₃₅, respectively, through a single bond.)

In Formula (3-5), R₃₃, T₃, W₃, V₃, X₃, p₃, s₃, u₃ and z₃ are the same as R₃₃, T₃, W₃, V₃, X₃, p₃, s₃, u₃ and z₃ in Formula (3-3). Ar₃₁, Ar₃₂, Ar₃₄ and Ar₃₅ are the same as Ar₃₁, Ar₃₂, Ar₃₄ and Ar₃₅ in Formula (3-2). Ar₃₃ and Ar₃₆ are the same as Ar₃₃ and Ar₃₆ in Formula (3-2). Z³², n₃ and m₃ are the same as Z³², n₃ and m₃ in Formula (3-2).

The monomer compound represented by Formula (3-5) may be synthesized by using the reaction as in Formula (3-4). Here, it is preferred that two polymerizable reaction moieties are simultaneously introduced in the last reaction process.

The crosslinking ratio may be controlled by the loading ratio (molar ratio) of each compound during the synthesis of the siloxane polymer (A-2), it is preferred that a monomer which becomes a pendant group bonded to one silicon atom for one Si—H of a polycondensate obtained by polycondensing the alkoxysilane is added by 1 to 1.2 times, and it is preferred that the monomer which becomes a pendant group bonded to two or more silicon atoms is added in a ratio which becomes a desired crosslinking ratio for a pendant group bonded to one silicon atom.

The reaction temperature in the synthesis is preferably 50° C. to 200° C., and more preferably 80° C. to 120° C. in view of increasing the decomposition of the monomer or the internal isomerization of double bonds, or the catalytic activity.

The reaction time significantly varies depending on the reactivity of the monomer, but is preferably 30 minutes to 3 days, and more preferably 30 minutes to 1 day. As the catalyst in the reaction, a platinum catalyst is suitably used. As the solvent, toluene is suitably used.

In addition, in the synthesis of the siloxane polymer (A-2), a polymerization initiator is not needed, and adverse effects are not caused by incorporation of the polymerization initiator in an organic electroluminescence device.

In the composition of the present invention, the blending ratio of the siloxane polymer (A) in the entire composition is preferably 50% by mass to 95% by mass, and more preferably 60% by mass to 90% by mass, based on the total solid content of the composition.

Further, the siloxane polymer (A) of the present invention may be used either alone or in combination of a plurality thereof (polymer blend).

[2] (B) Crosslinking Agent

The composition of the present invention contains at least one crosslinking agent (hereinafter also referred to as “crosslinking agent (B)”). The crosslinking agent which may be used in the composition of the present invention is not particularly limited as long as a crosslinking reaction proceeds between molecules of the crosslinking agent (B) and/or between the crosslinking agent (B) and the siloxane polymer (A) having a charge transporting moiety in the side chain thereof, and a known crosslinking agent may be effectively used.

At least one crosslinking agent (B) contains preferably (1) an alkoxysilane compound or a chlorosilane compound and/or (2) a compound having a plurality of vinyl groups. Hereinafter, each will be described.

(1) Alkoxysilane Compound or Chlorosilane Compound

When the composition of the present invention contains an alkoxysilane compound or a chlorosilane compound, a sol-gel reaction is conducted between the alkoxysilane compound or the chlorosilane compound by applying the composition and then heating the composition, and the crosslinking reaction is conducted by polycondensation of these compounds.

Examples of the alkoxysilane compound or the chlorosilane compound, which may be used in the composition of the present invention, include known compounds such as tetramethoxysilane, tetraethoxysilane, tetrabutoxysilane, phenethyltrimethoxysilane, benzyltriethoxysilane, phenyltrimethoxysilane, phenyltriethoxysilane, p-tolyltrimethoxysilane, 3-aminopropyltrimethoxysilane, 3-aminopropyltriethoxysilane, 3-(2-aminoethylamino)propyltrimethoxysilane, N-(6-aminohexyl)aminopropyltrimethoxysilane, (aminoethylaminomethyl)phenethyltrimethoxysilane, aminophenyltrimethoxysilane, pentafluorophenylpropyltrimethoxysilane, ethyltrimethoxysilane, propyltrimethoxysilane, n-octyltrimethoxysilane, 2-cyanoethyltrimethoxysilane, 2-cyanoethyltriethoxysilane, 3-cyanoethyltrimethoxysilane, bis(trimethoxysilyl)ethane, 1,4-bis(trimethoxysilylethyl)benzene, bis(trimethoxysilyl)hexane, bis(trimethoxysilylpropyl)amine, N,N′-bis[3-(trimethoxysilane)propyl]ethylenediamine, bis(triethoxysilyl)methane, bis(triethoxysilyl)ethane, (triethoxysilyl)octane, 1,9-bis(triethoxysilyl)nonane, tris(3-trimethoxysilylpropyl)isocyanurate, phenethyltrichlorosilane, p-tolyltrichlorosilane, 3-cyanopropyltrichlorosilane, 1,2-bis(trichlorosilyl)ethane, bis(trichlorosilyl)hexane and the like, and alkoxysilane is preferred and a tertiary alkoxysilane compound is more preferred.

The alkoxysilane compound or the chlorosilane compound which may be used in the composition of the present invention is also preferably a compound represented by the following Formula (S-1) or (S-2).

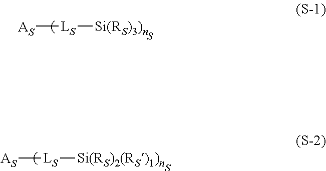

In Formulas (S-1) and (S-2), R_{S} represents a chlorine atom (Cl), a methoxy group (OCH₃) or an ethoxy group (OCH₂CH₃).

R_{S}′ represents a methyl group (CH₃), an ethyl group (CH₂CH₃) or a phenyl group (Ph).

L_{S} represents a divalent linking group having 3 or more carbon atoms.

A_{S} represents an n_{S}-valent functional group.

n_{S} represents an integer of 1 to 3. However, when n_{S} is 2 or 3, each R_{S}, each R_{S′} and each L_{S} may be the same as or different from every other R_{S}, every other R_{S′} and every other L_{S}.

Rₛ represents a chlorine atom (Cl), a methoxy group (OCH₃) or an ethoxy group (OCH₂CH₃), and is preferably a methoxy group or an ethoxy group.

R_{S′} represents a methyl group (CH₃), an ethyl group (CH₂CH₃) or a phenyl group (Ph), and is preferably a methyl group or an ethyl group.

L_{S} represents a divalent linking group having 3 or more carbon atoms. The divalent linking group L_{S} is preferably a divalent hydrocarbon group which may include an oxygen atom, a sulfur atom or a nitrogen atom, and more preferably an alkylene group, a cycloalkylene group, an arylene group, and a divalent group obtained by combination thereof, which may include an oxygen atom, a sulfur atom or a nitrogen atom.

A_{S} represents an n_{S}-valent functional group. Examples of a functional group represented by AS include any group, but include a known functional group, such as a phenyl group, an alkyl group, a perfluoroalkyl group, an amino group and the like, and preferably a phenyl group and an amino group. A functional group represented by A_{S} may have a charge transporting moiety and/or a vinyl group as described below, and a functional group represented by A_{S} itself may be a charge transporting moiety.

n_{S} represents an integer of 1 to 3. n_{S} is preferably 1.

The alkoxysilane compound or the chlorosilane compound may also have a charge transporting moiety and/or a vinyl group. Examples of the charge transporting moiety include a hole transporting moiety, an electron transporting moiety, a bipolar transportable moiety and the like, and specific examples and preferred examples thereof are the same as those of the charge transporting moiety represented by HL₁ described above. Further, the alkoxysilane compound or the chlorosilane compound further has a vinyl group, and thus in addition to a crosslinking reaction by the sol-gel reaction as described above, a reaction proceeds even between an Si—H group derived from the siloxane polymer (A) and the vinyl group to promote the crosslinking reaction, which is preferred.

Examples of the alkoxysilane compound/chlorosilane compound having a charge transporting moiety include known materials N-(3-trimethoxysilylpropyl)pyrrole, compounds described in APPROACHES TO ORGANIC LIGHT-EMITTERS VIA LAYER-BY-LAYER SELF-ASSEMBLY, Polym. Prepr., 1999, 40, 1196-1197, compounds described in Hole Mobilities in Sol-Gel Materials, Adv. Mater. Opt. Electron., 2000, 10, 69-79, compounds described in Air-stable, Cross-Linkable, Hole-Injection/Transporting Interlayers for Improved Charge Injection in Organic Light-Emitting Diodes, Chem. Mater., 2008, 20, 4873-4882, compounds described in Hybrid Organic-Inorganic Light-Emitting Diodes, Adv. Mate, 1999, 11, 2, 107-112 and the like. Hereinafter, specific examples of the alkoxysilane/chlorosilane compound having a charge transporting moiety described in these literatures will be shown, but the present invention is not limited thereto.

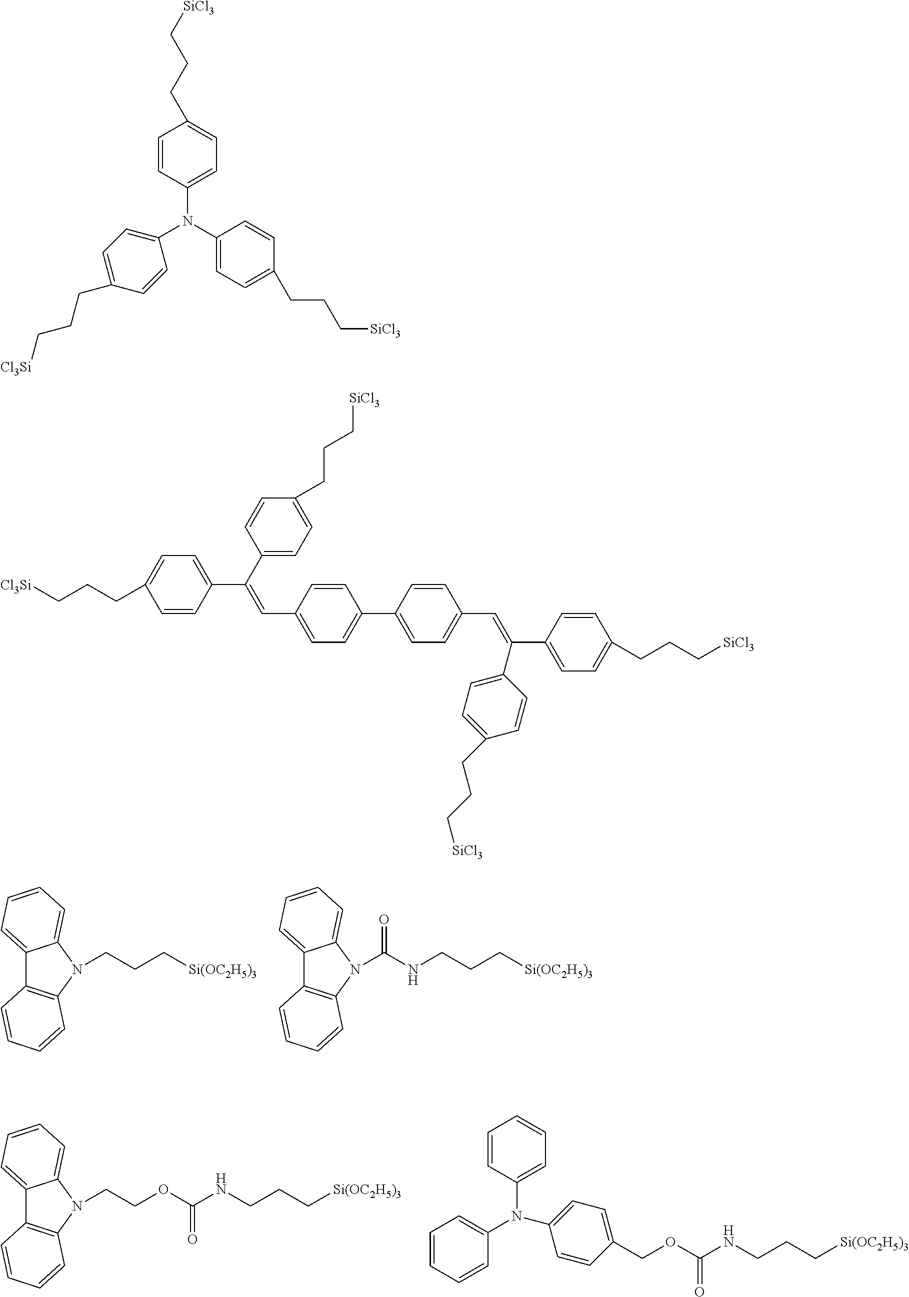

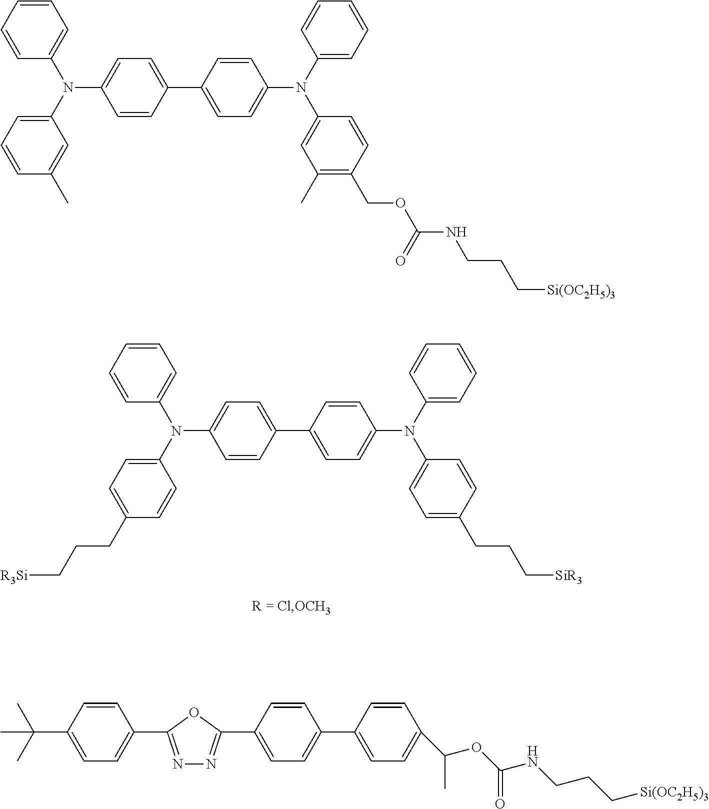

Examples of the alkoxysilane/chlorosilane compound having a vinyl group include known materials such as vinyltrimethoxysilane, vinyltriethoxysilane, vinyltrichlorosilane, p-styryltrimethoxysilane, styrylethyltrimethoxysilane, allyltrimethoxysilane, allyltriethoxysilane, allyltrichlorosilane and the like, the alkoxysilane compound is preferred, and vinyltrimethoxysilane, vinyltriethoxysilane, p-styryltrimethoxysilane, styrylethyltrimethoxysilane, allyltrimethoxysilane and allyltriethoxysilane are more preferred.

(2) Compound Having Plurality of Vinyl Groups

A compound having a plurality of vinyl groups which may be used in the composition of the present invention has preferably 2 or more vinyl groups, and more preferably 2 to 4 of vinyl groups. When the composition of the present invention contains a compound having a plurality of vinyl groups, a reaction proceeds between an Si—H group derived from the siloxane polymer (A) and the vinyl group, and a plurality of vinyl groups are present in one compound, and thus a crosslinking reaction proceeds.

Specific examples of the compound having a plurality of vinyl groups include butadiene, penta-1,4-diene, di(ethylene glycol)divinyl ether, divinyl benzene, 1,4-cyclohexanedimethanol divinyl ether, 1,4-butanediol divinyl ether, 1,3-divinyltetramethyldisiloxane, 2,4,6-triallyloxy-1,3,5-triazine, 1,3,5-triallyl-1,3,5-triazine-2,4,6(1H,3H,5H)-trione, allyl ether, octavinyl octasilasesquioxane, 2,4,6,8-tetramethyl-2,4,6,8-tetravinylcyclotetrasiloxane, VEctomer 4010, 4020, 4040, 4050, 4060, 4210, 4220, 4230(Morflex, Inc. trade name) and the like, and 1,3-divinyltetramethyldisiloxane and 2,4,6,8-tetramethyl-2,4,6,8-tetravinylcyclotetrasiloxane are more preferred.

The compound having a plurality of vinyl groups may also have a charge transporting moiety. Examples of the charge transporting moiety include a hole transporting moiety, an electron transporting moiety, a bipolar transportable moiety and the like, and preferred examples thereof are the same as specific examples and preferred examples of the charge transporting moiety represented by HL₁ described above.

Specific examples of the compound having a charge transporting moiety and a plurality of vinyl groups include compounds as described below, but the present invention is not limited thereto.

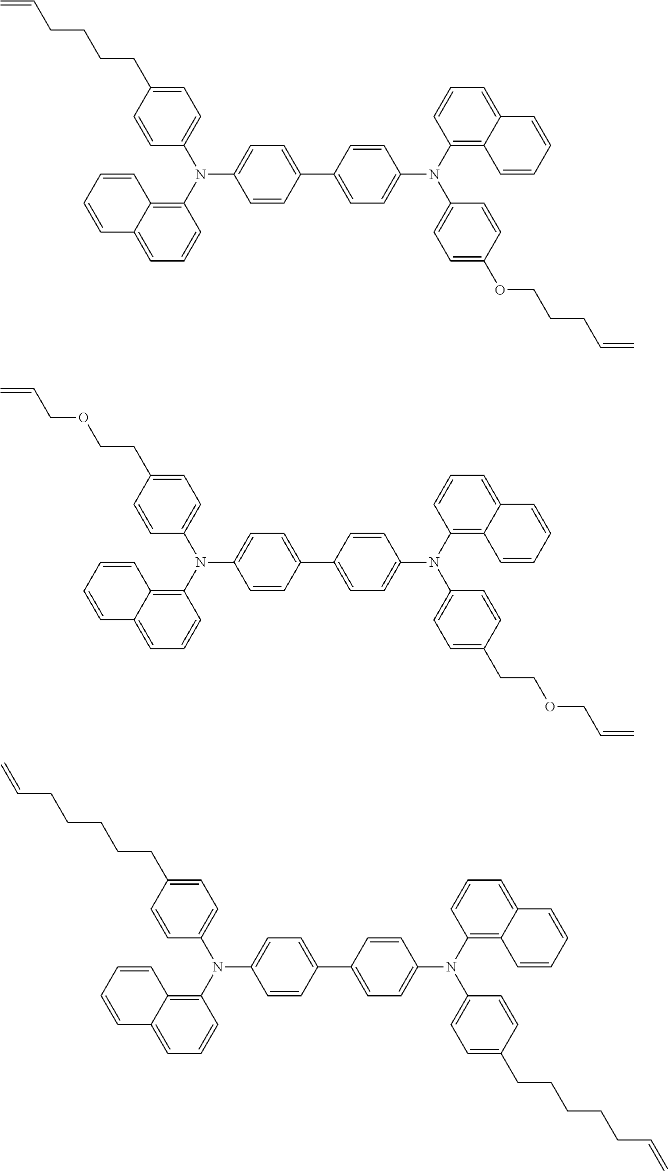

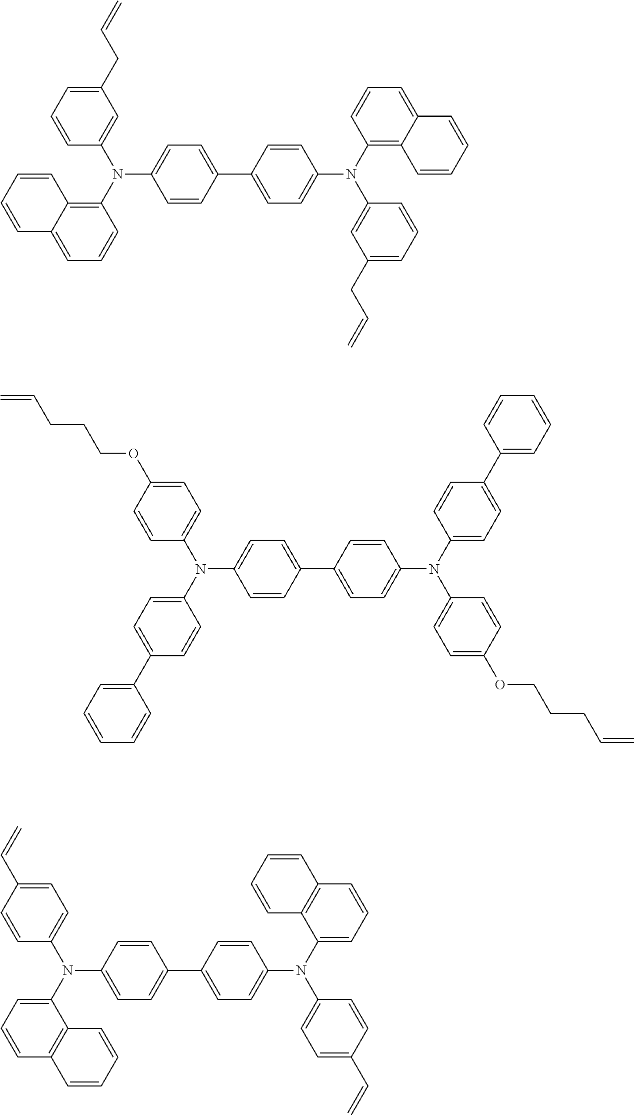 [SMILES: C=CCc1cccc(N(c2ccc(-c3ccc(N(c4cccc(CC=C)c4)c4cccc5ccccc45)cc3)cc2)c2cccc3ccccc23)c1 ; C=CCCCOc1ccc(N(c2ccc(-c3ccccc3)cc2)c2ccc(-c3ccc(N(c4ccc(OCCCC=C)cc4)c4ccc(-c5ccccc5)cc4)cc3)cc2)cc1 ; C=Cc1ccc(N(c2ccc(-c3ccc(N(c4ccc(C=C)cc4)c4cccc5ccccc45)cc3)cc2)c2cccc3ccccc23)cc1]

In the present invention, the crosslinking agent (B) may be used either alone or in combination of two or more thereof.

The content of the crosslinking agent (B) in the composition is preferably 5% by mass to 50% by mass, more preferably 10% by mass to 40% by mass, and still more preferably 10% by mass to 30% by mass, based on the total solid content of the composition.

[3] (C) Solvent

Examples of a solvent which may be used at the time of dissolving each component to prepare a composition include known organic solvents such as aromatic hydrocarbon-based solvents, alcohol-based solvents, ketone-based solvents, aliphatic hydrocarbon-based solvents, amide-based solvents and the like.

Examples of the aromatic hydrocarbon-based solvent include benzene, toluene, xylene, trimethyl benzene, tetramethyl benzene, cumene ethylbenzene, methylpropylbenzene, methylisopropylbenzene and the like, and toluene, xylene, cumene and trimethylbenzene are more preferred. The relative permittivity of the aromatic hydrocarbon-based solvent is typically 3 or less.

Examples of the alcohol-based solvent include methanol, ethanol, butanol, benzyl alcohol, cyclohexanol and the like, and butanol, benzyl alcohol and cyclohexanol are more preferred. The relative permittivity of the alcohol-based solvent is typically 10 to 40.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate and the like, and methyl isobutyl ketone and propylene carbonate are preferred. The relative permittivity of the ketone-based solvent is typically 10 to 90.

Examples of the aliphatic hydrocarbon-based solvent include pentane, hexane, octane, decane and the like, and octane and decane are preferred. The relative permittivity of the aliphatic hydrocarbon-based solvent is typically 1.5 to 2.0.

Examples of the amide-based solvent include N-methyl-2-pyrrolidone, N-ethyl-2-pyrrolidone, N,N-dimethylacetamide, N,N-dimethylformamide, 1,3-dimethyl-2-imidazolidinone and the like, and N-methyl-2-pyrrolidone and 1,3-dimethyl-2-imidazolidinone are preferred. The relative permittivity of the amide-based solvent is typically 30 to 40.

In the present invention, the above-described solvent may be used either alone or in combination of two or more thereof.

In the present invention, an aromatic hydrocarbon-based solvent (hereinafter also referred to as a “first solvent”) may be mixed with a second solvent having a relative permittivity higher than that of the first solvent and the mixture may be used. By using the mixed solvent, the hydrolysis of alkoxysilane is promoted, thereby improving the reactivity of the condensation.

As the second solvent, an alcohol-based solvent, an amide-based solvent and a ketone-based solvent are preferably used, and an alcohol-based solvent is more preferably used.

The mixing ratio (by mass) of the first solvent and the second solvent is 1/99 to 99/1, preferably 10/90 to 90/10, and more preferably 20/80 to 70/30. A mixed solvent containing the first solvent in an amount of 60% by mass or more is particularly preferred from the viewpoint of preventing the siloxane polymer from being precipitated.

[4] Formation of Film

The present invention also relates to a film formed by applying the composition of the present invention and heating the applied composition. Further, the film formed of the composition of the present invention is useful as a charge transporting layer. In addition, the present invention also relates to a method for forming a charge transporting layer, including applying the composition of the present invention and heating the applied composition.

The charge transporting layer is used preferably in a film thickness of 5 nm to 50 nm, and more preferably in a film thickness of 5 nm to 40 nm. Such a film thickness may be achieved by setting a solid content concentration in the composition to an appropriate range to achieve appropriate viscosity, thereby improving coatability and film-formation property.

The charge transporting layer is preferably a hole transporting layer, an electron transporting layer, an exciton blocking layer, a hole blocking layer, or an electron blocking layer, more preferably a hole transporting layer or an exciton blocking layer, and still more preferably a hole transporting layer.

A total solid content concentration in the composition of the present invention is generally 0.05% by mass to 30% by mass, more preferably 0.1% by mass to 20% by mass, and still more preferably 0.1% by mass to 10% by mass.

The viscosity in the composition of the present invention is generally 1 mPa·s to 30 mPa·s, more preferably 1.5 mPa·s to 20 mPa·s, and still more preferably 1.5 mPa·s to 15 mPa·s.

The composition of the present invention is used by dissolving the above-described components in a predetermined organic solvent and subjecting the solution to filter filtration, followed by applying the composition on a predetermined support or layer as follows. The filter which is used for the filter filtration is preferably a filter made of polytetrafluoroethylene, polyethylene or nylon and having a pore size of 2.0 μm or less, more preferably 0.5 μm or less, and still more preferably 0.3 μm or less.

An application method of the composition of the present invention is not particularly limited, and layers may be formed by any application method known in the related art. Examples of the application method include an inkjet method, a spray coating method, a spin coating method, a bar coating method, a transfer method, a printing method and the like.

The composition of the present invention is applied and then heated, and thus a crosslinking reaction proceeds between molecules of the crosslinking agent (B) and/or between the crosslinking agent (B) and the siloxane polymer (A) having a charge transporting moiety at a side chain thereof.

The heating temperature and time after the application are not particularly limited as long as the crosslinking reaction proceeds, but the heating temperature is generally 100° C. to 200° C., and preferably 120° C. to 160° C. The heating time is generally 1 minute to 120 minutes, preferably 1 minute to 60 minutes, and more preferably 1 minute to 30 minutes.

Further, as long as the crosslinking reaction proceeds, it is possible to perform the crosslinking reaction by the following polymerization method instead of heating. Examples thereof include a crosslinking reaction by UV irradiation, a crosslinking reaction by a platinum catalyst, a crosslinking reaction by an iron catalyst such as iron chloride and the like, and the like. These polymerization methods may be used in combination with a polymerization method by heating.

[5] Organic Electroluminescence Device

The organic electroluminescence device in the present invention will be described in detail.

The organic electroluminescence device in the present invention has a charge transporting layer which is formed of the composition of the present invention.

More specifically, the organic electroluminescence device in the present invention is an organic electroluminescence device including a pair of electrodes including an anode and a cathode on a substrate and at least one organic layer including a light emitting layer between the electrodes, in which a charge transporting layer which is formed of the composition of the present invention is included as the at least one organic layer.

In the organic electroluminescence device of the present invention, the light emitting layer is an organic layer, and at least one organic layer is also included between the light emitting layer and the anode. However, an organic layer may be further included in addition to the organic layers.

In view of the properties of the luminescence device, it is preferred that at least one electrode of the anode and the cathode is transparent or semi-transparent.

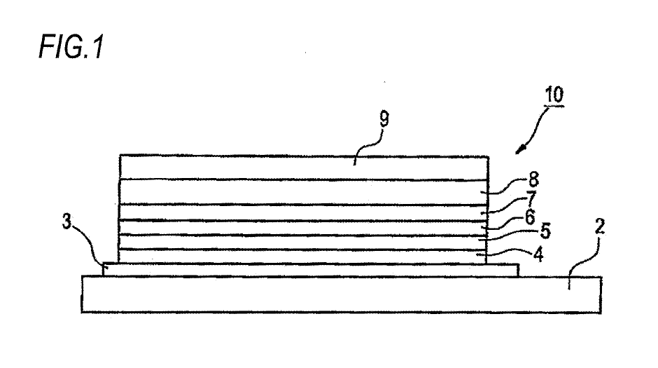

FIG. 1 illustrates an example of the configuration of an organic electroluminescence device according to the present invention.

In an organic electroluminescence device 10 according to the present invention, which is illustrated in FIG. 1, a light emitting layer 6 is interposed between an anode 3 and a cathode 9 on a supporting substrate 2. Specifically, a hole injection layer 4, a hole transporting layer 5, the light emitting layer 6, a hole blocking layer 7, and an electron transporting layer 8 are stacked in this order between the anode 3 and the cathode 9.

<Configuration of Organic Layer>

The layer configuration of the organic layer is not particularly limited and may be appropriately selected depending on a use and a purpose of the organic electroluminescence device, but it is preferred that the organic layer is formed on a transparent electrode or a back electrode. In this case, the organic layer is formed on the entire surface or partial surface of the above-described transparent electrode or the above-described back electrode.

The shape, size, thickness and the like of the organic layer are not particularly limited and may be appropriately selected depending on the purpose.

Specific examples of the layer configuration may include the followings, but the present invention is not limited to these configurations.
Anode/hole transporting layer/light emitting layer/electron transporting layer/cathode,
   Anode/hole transporting layer/light emitting layer/blocking layer/electron transporting layer/cathode,
   Anode/hole transporting layer/light emitting layer/blocking layer/electron transporting layer/electron injection layer/cathode,
   Anode/hole injection layer/hole transporting layer/light emitting layer/electron transporting layer/electron injection layer/cathode,
   Anode/hole injection layer/hole transporting layer/light emitting layer/blocking layer/electron transporting layer/cathode,
   Anode/hole injection layer/hole transporting layer/light emitting layer/blocking layer/electron transporting layer/electron injection layer/cathode.
   Anode/hole injection layer/hole transporting layer/exciton blocking layer/light emitting layer/electron transporting layer/electron injection layer/cathode.

The device configuration, substrate, cathode and anode of the organic electroluminescence device are described in detail in, for example, the official gazette of Japanese Patent Application Laid-Open No. 2008-270736, and the matters described in the official gazette may be applied to the present invention.

<Substrate>

The substrate used in the present invention is preferably a substrate which does not scatter or decay light generated from the organic layer. In the case of an organic material, it is preferred that the organic material is excellent in heat resistance, dimensional stability, solvent resistance, electrical insulation properties and processability.

<Anode>

Typically, the anode may have a function as an electrode for supplying a hole to the organic layer, is not particularly limited with respect to shape, structure, size and the like and may be appropriately selected among the known electrode materials depending on a use or purpose of the luminescence device. As described above, the anode is usually formed as a transparent anode.

<Cathode>

Typically, the cathode may have a function as an electrode for injecting an electron into the organic layer, is not particularly limited with respect to shape, structure, size and the like and may be appropriately selected among the known electrode materials depending on a use or purpose of the luminescence device.

With respect to the substrate, the anode and the cathode, the matters described in paragraph Nos. [0070] to [0089] of the official gazette of Japanese Patent Application Laid-Open No. 2008-270736 may be applied to the present invention.

<Organic Layer>

The organic layer in the present invention will be described.

[Formation of Organic Layer]

In the organic electroluminescence device of the present invention, each organic layer may be appropriately formed by any one of a dry film-forming method such as a vapor deposition method, a sputtering method or the like, and a solution application process such as a transfer method, a printing method, a spin coating method, a bar coating method, an inkjet method, a spraying method and the like.

In addition to the charge transporting layer which is formed of the composition of the present invention, it is particularly preferred that any one layer of the organic layers is film-formed by a wet method. In addition, other layers may be film-formed by appropriately selecting a dry method or a wet method. The adoption of a wet method is preferred because a large area of the organic layer may be easily realized, and a luminescence device with high luminance intensity and excellent light emission efficiency is efficiently obtained at low costs. A vapor deposition method, a sputtering method or the like may be used as the dry method, and a dipping method, a spin coating method, a dip coating method, a casting method, a die coating method, a roll coating method, a bar coating method, a gravure coating method, a spray coating method, an inkjet method, or the like may be used as the wet method. These film forming methods may be appropriately selected depending on the material of the organic layer. In the case of forming the film by means of a wet method, drying may be performed after the film formation. Drying is performed by selecting a condition of temperature, pressure and the like, such that the coating layer is not damaged.

The coating liquid used in the above-described wet film-forming method (application process) is usually composed of a material of the organic layer and a solvent for dissolving or dispersing the material therein. The solvent is not particularly limited, and may be selected depending on the material to be used in the organic layer. Specific examples of the solvent include halogen-based solvents (chloroform, carbon tetrachloride, dichloromethane, 1,2-dichloroethane, chlorobenzene and the like), ketone-based solvents (acetone, methyl ethyl ketone, diethyl ketone, n-propyl methyl ketone, cyclohexanone and the like), aromatic solvents (benzene, toluene, xylene and the like), ester-based solvents (ethyl acetate, n-propyl acetate, n-butyl acetate, methyl propionate, ethyl propionate, γ-butyrolactone, diethyl carbonate and the like), ether-based solvents (tetrahydrofuran, dioxane and the like), amide-based solvents (dimethylformamide, dimethylacetamide and the like), dimethyl sulfoxide, alcohol-based solvents (methanol, propanol, butanol and the like), water, and the like.

Among the above-described solvents, ketone-based solvents, aromatic solvents, ester-based solvents, ether-based solvents or alcohol-based solvents are preferred.

Meanwhile, the solid content with respect to the solvent in the coating liquid is not particularly limited, and the viscosity of the coating liquid may also be arbitrarily selected according to the film forming method.

[Light Emitting Layer]

In the organic electroluminescence device of the present invention, the light emitting layer contains a light emitting material, but it is preferred that the light emitting material contains a phosphorescent light emitting compound. The phosphorescent light emitting compound is not particularly limited as long as the compound is a compound capable of emitting light from a triplet exciton. As the phosphorescent light emitting compound, it is preferred that an ortho-metalated complex or a porphyrin complex is used, and it is more preferred that an ortho-metalated complex is used. Among the porphyrin complexes, a porphyrin platinum complex is preferred. The phosphorescent light emitting compound may be used either alone or in combination of two or more thereof.

The ortho-metalated complex as referred to in the present invention is a generic name of a group of compounds described in “Organometallic Chemistry-Principles and Applications” written by YAMAMOTO, Akio, pages 150 and 232, SHOKABO PUBLISHING Co., Ltd. (1982), “Photochemistry and Photophysics of Coordination Compounds” written by H. Yersin, pages 71 to 77 and 135 to 146, Springer-Verlag Inc. (1987), and the like. A ligand for forming the ortho-metalated complex is not particularly limited, but is preferably a 2-phenylpyridine derivative, a 7,8-benzoquinoline derivative, a 2-(2-thienyl)pyridine derivative, a 2-(1-naphthyl)pyridine derivative or a 2-phenylquinoline derivative. These derivatives may have a substituent. Further, the derivative may have ligands other than the ligand which is essential for forming these ortho-metalated complexes. As a central metal for forming the ortho-metalated complex, any metal may be used as long as the central material is a transition metal. In the present invention, rhodium, platinum, gold, iridium, ruthenium, palladium or the like may be preferably used. Among them, iridium is particularly preferred. The organic layer including such an ortho-metalated complex has excellent light emission luminance intensity and light emission efficiency. As for the ortho-metalated complex, specific examples thereof are also described in paragraph Nos. [0201] to [0231] of Japanese Patent Application Laid-Open No. 2002-319491.

The ortho-metalated complex which is used in the present invention may be synthesized by known techniques as described in Inorg. Chem., 30, 1685, 1991, Inorg. Chem., 27, 3464, 1988, Inorg. Chem., 33, 545, 1994, Inorg. Chim. Acta, 181, 245, 1991, J. Organomet. Chem., 335, 293, 1987, J. Am. Chem. Soc., 107, 1431, 1985, and the like.

A content of the phosphorescent light emitting compound in the light emitting layer is not particularly limited, but is, for example, 0.1% by mass to 70% by mass, and preferably 1% by mass to 20% by mass. When the content of the phosphorescent light emitting compound is less than 0.1% by mass or more than 70% by mass, the effect thereof may not be sufficiently exhibited in some cases.

In the present invention, the light emitting layer may contain a host compound, if necessary.

The host compound is a compound which causes energy transfer in an excited state thereof to the phosphorescent light emitting compound, and as a result, causes light emission of the phosphorescent light emitting compound. Specific examples thereof include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidene compounds, porphyrin compounds, anthraquinodimethane derivatives, anthrone derivatives, diphenylquinone derivatives, thiopyrane dioxide derivatives, carbodiimide derivatives, fluorenylidenemethane derivatives, distyrylpyrazine derivatives, heterocyclic tetracarboxylic acid anhydrides such as naphthalene perylene and the like, phthalocyanine derivatives, metal complexes of 8-quinolinol derivatives, metal complexes having metal phthalocyanine, benzoxazole, benzothiazole, or the like as a ligand, polysilane compounds, poly(N-vinylcarbazole) derivatives, aniline copolymers, thiophene oligomers, electrically conductive polymers such as polythiophene and the like, polythiophene derivatives, polyphenylene derivatives, polyphenylene vinylene derivatives, polyfluorene derivatives, and the like. The host compound may be used either alone or in combination of two or more thereof.

A thickness of the light emitting layer is preferably 10 nm to 200 nm, and more preferably 20 nm to 80 nm. When the thickness thereof exceeds 200 nm, the driving voltage may increase in some cases, and when the thickness thereof is less than 10 nm, a short circuit of the luminescence device may occur in some cases.

(Hole Injection Layer and Hole Transporting Layer)

The organic electroluminescence device of the present invention may have a hole injection layer and a hole transporting layer. Each of the hole injection layer and the hole transporting layer is a layer having a function to receive a hole from the anode or anode side and to transport the hole into the cathode side.

The hole injection layer and the hole transporting layer are described in detail in, for example, Japanese Patent Application Laid-Open Nos. 2008-270736 and 2007-266458, and the matters described in these official gazettes may be applied to the present invention.

It is preferred that the siloxane polymer according to the present invention is contained in a hole injection layer, a hole transporting layer or an electron blocking layer.

(Electron Injection Layer and Electron Transporting Layer)

The organic electroluminescence device of the present invention may have an electron injection layer and an electron transporting layer. Each of the electron injection layer and the electron transporting layer is a layer having a function to receive an electron from the cathode or the cathode side to transport the electron into the anode side. Each of an electron injection material and an electron transporting material used in these layers may be a low molecular weight compound, or may be a polymer compound.

The electron injection layer and the electron transporting layer are described in detail in, for example, Japanese Patent Application Laid-Open Nos. 2008-270736 and 2007-266458, and the matters described in these official gazettes may be applied to the present invention.

(Hole Blocking Layer)

The hole blocking layer is a layer having a function to prevent a hole transported from the anode side into the light emitting layer from going therethrough into the cathode side. In the present invention, the hole blocking layer may be formed as an organic layer adjacent to the light emitting layer on the cathode side.

Examples of the organic compound constituting the hole blocking layer include an aluminum complex such as aluminum(III)bis(2-methyl-8-quinolinato)4-phenylphenolate (abbreviated as BAlq) and the like, triazole derivatives, phenanthroline derivatives such as 2,9-dimethyl-4,7-diphenyl-1,10-phenanthroline (abbreviated as BCP) and the like, triphenylene derivatives, carbazole derivatives, and the like.

The thickness of the hole blocking layer is preferably 1 nm to 500 nm, more preferably 5 nm to 200 nm, and still more preferably 10 nm to 100 nm.

The hole blocking layer may be a single layer structure composed of one or two or more kinds of the above-described materials or may be a multilayer structure composed of a plurality of layers of the same or different compositions.

(Electron Blocking Layer)

The electron blocking layer is a layer having a function to prevent an electron transported from the cathode side into the light emitting layer from going therethrough into the anode side. In the present invention, the electron blocking layer may be formed as an organic layer adjacent to the light emitting layer on the anode side.

As an example of the organic compound constituting the electron blocking layer, for example, those exemplified as the above-described hole transporting material may be applied.

The thickness of the electron blocking layer is preferably 1 nm to 500 nm, more preferably 5 nm to 200 nm, and still more preferably 10 nm to 100 nm.

The electron blocking layer may be a single layer structure composed of one or two or more kinds of the above-described materials, or may be a multilayer structure composed of a plurality of layers of the same or different compositions.

(Explanation of Exciton Blocking Layer)

An exciton blocking layer is a layer which is formed on either one or both of an interface between the light emitting layer and the hole transporting layer or interface between the light emitting layer and the electron transporting layer, and is a layer for preventing an exciton produced in the light emitting layer from being diffused into the hole transporting layer or the electron transporting layer to be deactivated without causing light emission from occurring. The exciton blocking layer is preferably composed of a carbazole derivative.

[Other Organic Layers]

The organic electroluminescence device of the present invention may have a protective layer as described in Japanese Patent Application Laid-Open Nos. H7-85974, H7-192866, H8-22891, H10-275682, H10-106746, and the like. The protective layer is formed on the uppermost surface of the luminescence device. The uppermost surface herein refers to an outer surface of a back electrode in the case of stacking a base material, a transparent electrode, an organic layer and the back electrode in this order, and the uppermost surface refers to an outer surface of a transparent electrode in the case of stacking a base material, a back electrode, an organic layer and the transparent electrode in this order. The shape, size, thickness and the like of the protective layer are not particularly limited. A material constituting the protective layer is not particularly limited as long as the material has a function to suppress a substance which may deteriorate the luminescence device, such as moisture, oxygen or the like, from penetrating or permeating into the device, and silicon oxide, silicon dioxide, germanium oxide, germanium dioxide or the like may be used.

A method of forming the protective layer is not particularly limited, and it is possible to apply, for example, a vacuum vapor deposition method, a sputtering method, a reactive sputtering method, a molecular beam epitaxy method, a cluster-ion beam method, an ion plating method, a plasma polymerization method, a plasma CVD method, a laser CVD method, a thermal CVD method, a coating method, or the like.

[Sealing]

Further, it is preferred that a sealing layer for preventing moisture or oxygen from penetrating is formed on the organic electroluminescence device. As a material for forming the sealing layer, it is possible to use copolymers of tetrafluoroethylene and at least one co-monomer, fluorine-containing copolymers having a cyclic structure in a copolymer main chain thereof, polyethylene, polypropylene, polymethyl methacrylate, polyimide, polyurea, polytetrafluoroethylene, polychlorotrifluoro ethylene, polydichlorodifluoroethylene, copolymers of chlorotrifluoroethylene or dichlorodifluoroethylene and another co-monomer, water-absorbing substances having a water absorption ratio of 1% or more; moisture-proof substances having a water absorption ratio of 0.1% or less, metals (In, Sn, Pb, Au, Cu, Ag, Al, Tl, Ni and the like), metal oxides (MgO, SiO, SiO₂, Al₂O₃, GeO, NiO, CaO, BaO, Fe₂O₃, Y₂O₃, TiO₂ and the like), metal fluorides (MgF₂, LiF, AlF₃, CaF₂ and the like), liquid fluorinated carbons (e.g., perfluoroalkanes, perfluoroamines, perfluoroethers and the like), substances obtained by dispersing an adsorbent of moisture or oxygen in the liquid fluorinated carbon, and the like.

In the organic electroluminescent device of the present invention, light emission may be obtained by applying direct current (alternating current components may be included, if necessary) voltage (usually 2 volts to 15 volts) or a direct current between the anode and the cathode.

As for the driving method of the organic electroluminescence device of the present invention, it is possible to apply the driving methods as described in each official gazette of Japanese Patent Application Laid-Open Nos. H2-148687, H6-301355, H5-29080, H7-134558, H8-234685 and H8-241047, and each specification of Japanese Patent No. 2784615, U.S. Pat. Nos. 5,828,429 and 6,023,308, and the like.

### EXAMPLE

Hereinafter, the present invention will be described in more detail with reference to the Examples. The materials, reagents, amounts and ratios of substances, operations and the like shown in the following Examples may be appropriately changed unless deviating from the gist of the invention. Therefore, the scope of the present invention is not limited to the following specific examples.

<Synthesis of Siloxane Polymer Having Charge Transporting Moiety at Side Chain>

First, Compound 1e, which is a monomer, was synthesized according to the following scheme.

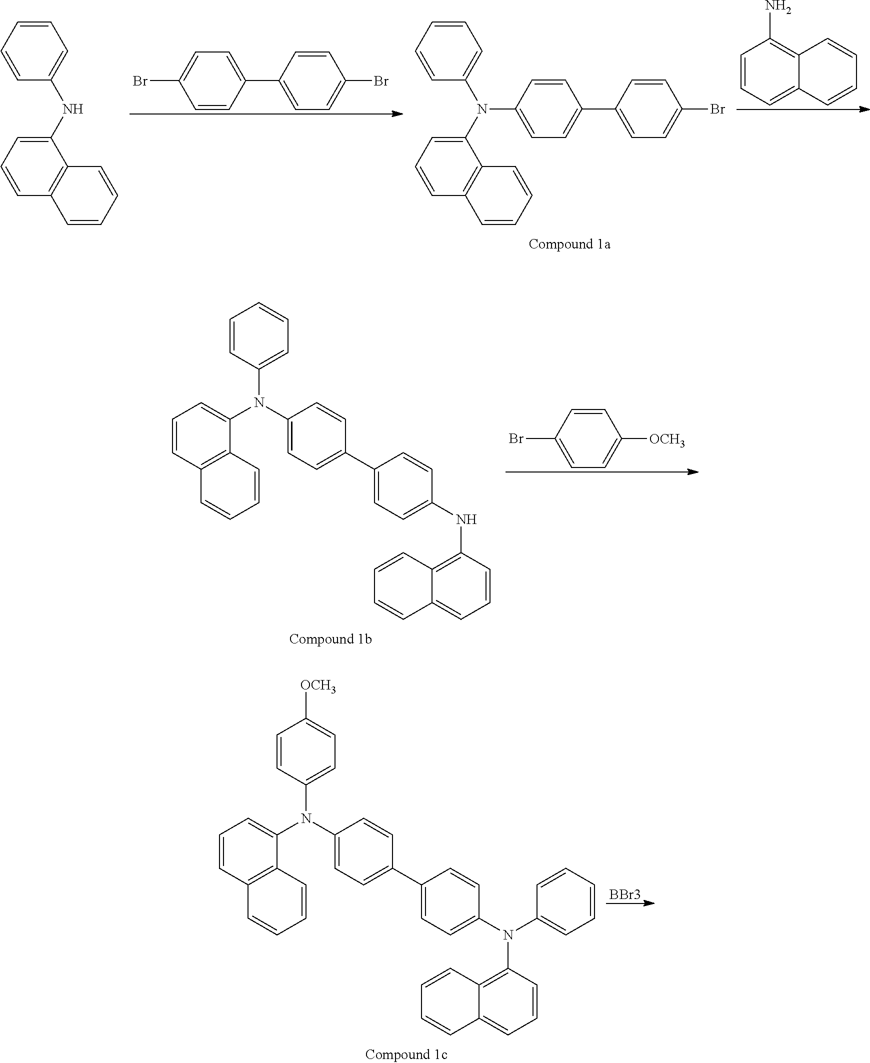

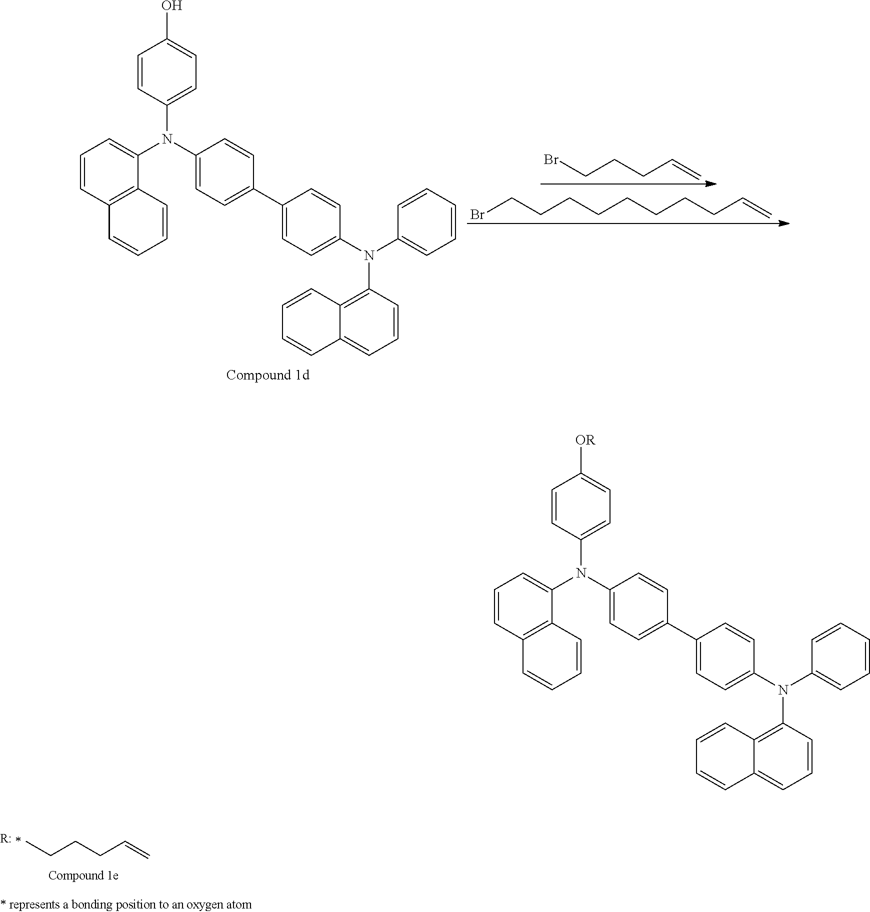

### Synthesis of Compound 1a

Bis(dibenzylideneacetone)palladium (manufactured by Tokyo Chemical Industry Co., Ltd.) (4.2 g) and 1,1′-bis(diphenylphosphino)ferrocene (manufactured by Tokyo Chemical Industry Co., Ltd.) (4.4 g) were stirred in a toluene solution (1,800 mL) under an inert atmosphere for 10 minutes, and then N-phenyl-1-napthylamine (manufactured by Tokyo Chemical Industry Co., Ltd.) (80 g), 4,4′-dibromobiphenyl (manufactured by Wako Pure Chemical Industries, Ltd.) (204.8 g) and sodium tert-butoxide (manufactured by Tokyo Chemical Industry Co., Ltd.) (42.1 g) were added thereto. The reaction was performed under an inert atmosphere at 100° C. for 6 hours, and then water and ethyl acetate were poured thereto. The organic layer was washed with a saline solution, dried over magnesium sulfate, and then concentrated under reduced pressure. The concentrated residue was purified by silica gel column chromatography (eluent: ethyl acetate/hexane=1/30) to obtain Compound 1a (147.8 g).

### Synthesis of Compound 1b

Bis(dibenzylideneacetone)palladium (4 g) and 1,1′-bis(diphenylphosphino)ferrocene (3.6 g) were stirred in a toluene solution (2,800 mL) under an inert atmosphere for 10 minutes, and then Compound 1a (144 g), 1-napthylamine (manufactured by Tokyo Chemical Industry Co., Ltd.) (122.4 g) and sodium tert-butoxide (39.2 g) were added thereto. The reaction was performed under an inert atmosphere at 100° C. for 6 hours, and then water and ethyl acetate were poured thereto. The organic layer was washed with a saline solution, dried over magnesium sulfate, and then concentrated under reduced pressure. The concentrated residue was purified by silica gel column chromatography (eluent: ethyl acetate/hexane=1/20) to obtain Compound 1b (122 g).

### Synthesis of Compound 1c

Hexamethyldisilazane lithium (1.6 mol/L THF solution) was added dropwise to a THF (tetrahydrofuran) solution (140 mL) of bis(dibenzylideneacetone)palladium (1.34 g), 2-dicyclohexylphosphino-2′-dimethylaminobiphenyl (manufactured by Tokyo Chemical Co., Ltd.) (1.02 g), Compound 1b (60 g) and 4-bromoanisole (manufactured by Tokyo Chemical Industry Co., Ltd.) (24 g) at room temperature under an inert atmosphere, and then the temperature was increased to 65° C., followed by stirring for 2 hours. After the reaction was completed, water and ethyl acetate were poured thereto to wash the organic layer with a saline solution. The organic layer was dried over magnesium sulfate, and then concentrated under reduced pressure. The concentrated residue was purified by silica gel column chromatography (eluent: ethyl acetate/hexane=2/1) to obtain Compound 1c (24 g).

### Synthesis of Compound 1d

1 M boron tribromide in CH₂Cl₂ (manufactured by Aldrich) (34 mL) was added dropwise to a dichloromethane solution of Compound 1c (16 g) under ice cooling. Thereafter, the temperature was increased to room temperature and followed by stirring for 1 hour. After the reaction was completed, water and ethyl acetate were poured thereto to wash the organic layer with a saline solution. The organic layer was dried over magnesium sulfate, and then concentrated under reduced pressure. The concentrated residue was purified by silica gel column chromatography (eluent: ethyl acetate/hexane=1/3) to obtain Compound 1d (15.2 g).

### Synthesis of Compound 1e

Compound 1d (0.6 g), 5-bromo-1-pentene (manufactured by Tokyo Chemical Industry Co., Ltd.) (0.17 g) and potassium carbonate (0.54 g) were stirred in dimethylacetamide (6.5 mL) under an inert atmosphere for 12 hours. After the reaction was completed, water and ethyl acetate were poured thereto to wash the organic layer with a saline solution. The organic layer was dried over magnesium sulfate, and then concentrated under reduced pressure. Compound 1e (0.53 g) was obtained by recrystallizing the concentrated residue in a toluene solvent.

### Synthesis Example 1

### Synthesis of Arylamine Pendant-Type Siloxane Polymer 1

A toluene solution of Compound 1e (0.5 g) and poly(methylhydrosiloxane) (molecular weight=2,100 to 2,400, mol % of MeHSiO=100%, and hereinafter, the arylamine pendant-type siloxane polymer synthesized with the polymer will be referred to as a 35-mer) (43 mg) was stirred at 80° C. under a nitrogen atmosphere for 10 minutes. 10 mg of dichloro(dicyclopentadiene)platinum was added to the reaction solution, and followed by stirring for 12 hours. The reaction solution was concentrated under reduced pressure, and the concentrate was added dropwise to an IPA (isopropyl alcohol) solvent to obtain a precipitate. An excessive amount of Compound 1e was removed by repeating the reprecipitation purification several times with a solvent of isopropyl alcohol/ethyl acetate=3/2 (volume ratio) in a toluene solution of the precipitate. As the molecular weight of the obtained Arylamine Pendant-Type Siloxane Polymer 1, Mn=14,900 and Mw=23,800, and the structure thereof was confirmed by NMR. Further, it can be known that unreacted Si—H is present in an amount of 6 mol % from the GPC and NMR measurement of the Arylamine Pendant-Type Siloxane Polymer 1 (unreacted Si—H is obtained by the following equation).

Ratio of unreacted Si—H=(theoretical molecular weight in the case of 100% reaction—molecular weight obtained by GPC measurement)/59 (molecular weight of MeSiO)/number of units in MeSiO (35 in Synthetic Example 1)

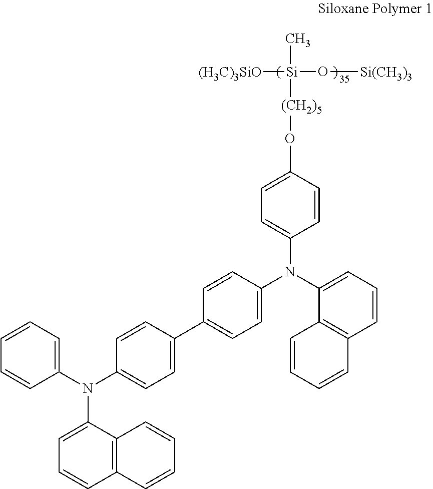

### Synthesis Example 2

### Synthesis of Carbazole Pendant-Type Siloxane Polymer 2

A solution including allyl carbazole and Carbazole Pendant-Type Siloxane Polymer 2 was obtained according to Examples 8 and 9 described in U.S. Pat. No. 5,414,059. The reaction solution was concentrated under reduced pressure, and the concentrate was added dropwise to an IPA solvent to obtain a precipitate. The reprecipitation purification was repeated several times with a solvent of isopropyl alcohol/ethyl acetate=3/2 (volume ratio) in a toluene solution of the precipitate and drying under vacuum to obtain a white solid. As the molecular weight of the obtained Carbazole Pendant-Type Siloxane Polymer 2, Mn=7,300 and Mw=16,400.

### A. Examples A-1 to A-4 and Comparative Examples A-1 and A-2

### Manufacture of Green Luminescence Device

### Example A-1

### Preparation of Coating Liquid a for Forming Hole Transporting Layer

80% by mass of Siloxane Polymer 1 having NPD at a side chain thereof and 20% by mass of Crosslinking Agent A were dissolved in xylene for electronic industrial use to prepare a solution having a total solid content concentration of 0.4% by mass, and the solution was filtered with a PTFE (polytetrafluoroethylene) filter having a pore size of 0.22 μm, thereby preparing Coating Liquid A for forming a hole transporting layer.

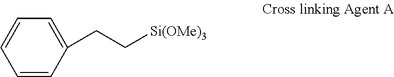

<Preparation of Coating Liquid a for Forming Light Emitting Layer>

95% by mass of Host Compound H-1 and 5% by mass of Light Emitting Material E-1 were dissolved in methyl ethyl ketone (MEK) to prepare a solution having a solid content concentration of 1.0% by mass, and the solution was filtered with a PTFE (polytetrafluoroethylene) filter having a pore size of 0.22 μm, thereby preparing Coating Liquid A for forming a light emitting layer.

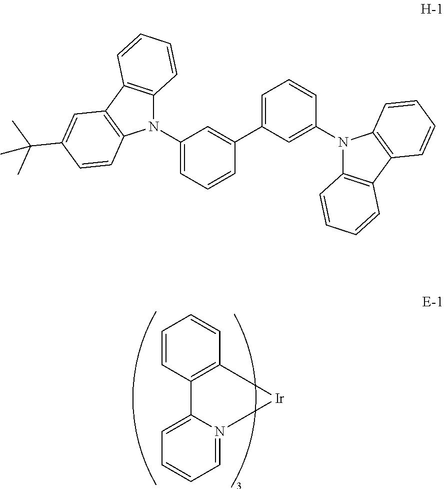

<Manufacture of Device>

On a glass substrate of 25 mm×25 mm×0.7 mm, ITO was subjected to vapor deposition in a thickness of 150 nm to form a film and use the film as a transparent supporting substrate. The transparent supporting substrate was put in a washing vessel, ultrasonically washed in 2-propanpl, and then subjected to a UV-ozone treatment for 30 minutes.

2 parts by mass of PTPDES (weight average molecular weight Mw=13,100, manufactured by CHEMIPRO KASEI KAISHA Ltd., and n means a repeating number of the structure within the parenthesis and represents an integer) represented by the following structural formula was dissolved in 98 parts by mass of cyclohexanone for electronic industrial use (manufactured by Kanto Chemical Industry Co., Ltd.), and the solution was spin coated (2,500 rpm, for 20 seconds) on the glass substrate having the ITO so as to have a thickness of about 40 nm, dried at 120° C. for 10 minutes, and then subjected to an annealing treatment at 160° C. for 60 minutes, thereby film-forming a hole injection layer.

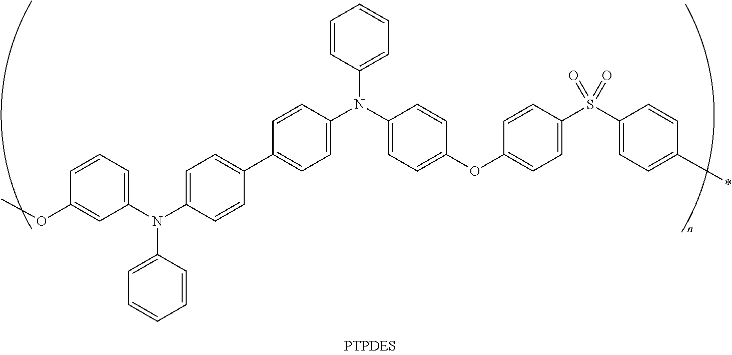

Coating Liquid A for forming a hole transporting layer prepared as described above was spin coated (1,500 rpm, for 20 seconds) on the hole injection layer so as to have a thickness of about 10 nm, dried at 120° C. for 30 minutes, and then subjected to an annealing treatment at 150° C. for 10 minutes, thereby film-forming a hole transporting layer.

Coating Liquid A for forming a light emitting layer prepared as described above was spin coated (1,500 rpm, for 20 seconds) on the hole transporting layer so as to have a thickness of about 30 nm within a glove box (dew point of −68° C., oxygen concentration of 10 ppm), thereby preparing a light emitting layer.

Subsequently, BAlq (bis-(2-methyl-8-quinolinolato)-4-(phenyl-phenolate)-aluminum (III)) represented by the following Structural Formula was formed as an electron transporting layer on the light emitting layer by means of a vacuum vapor deposition method so as to have a thickness of 40 nm.

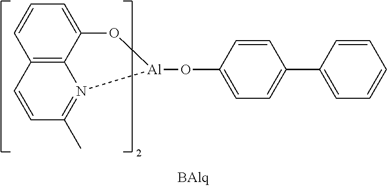

Lithium fluoride (LiF) was formed as an electron injection layer on the electron transporting layer by means of a vacuum vapor deposition method so as to have a thickness of 1 nm. Further, metallic aluminum was vapor deposited to 70 nm thereon, thereby forming a cathode.

The laminate thus manufactured was placed in an argon gas-substituted glove box and sealed by using a stainless steel-made sealing can and an ultraviolet ray-curable adhesive (XNR5516HV, manufactured by Nagase Ciba Ltd.), thereby manufacturing Organic Electroluminescence Device A-1.

### Examples A-2 and A-3 and Comparative Example A-1

Devices in Examples A-2 and A-3 were obtained in the same manner as in Example A-1, except that a crosslinking agent described in the following Table 1 was used in the preparation of Coating Liquid A for forming a hole transporting layer in Example A-1. In addition, for comparison, a device in Comparative Example A-1 was obtained in the same manner as in Example A-1, except that a crosslinking agent was not used in the preparation of Coating Liquid A for forming a hole transporting layer in Example A-1.

### Example A-4 and Comparative Example A-2

A device in Example A-4 was obtained in the same manner as in Example A-1, except that a light emitting layer having a film thickness of 30 nm was formed by vapor depositing 95% by mass of Host Compound H-1 and 5% by mass of Light Emitting Material E-1 by means of a vacuum vapor deposition method, instead of forming a light emitting layer by means of application using Coating Liquid A for forming a light emitting layer in the manufacture of a device in Example A-1.

Further, for comparison, a device in Comparative Example A-2 was obtained in the same manner as in Example A-4, except that a crosslinking agent was not used in the formation of a hole transporting layer in Example A-4.

<Evaluation of Device>

(a) Efficiency

A voltage of direct current was applied on each device by using a Source Measure Unit 2400 manufactured by TOYO CORPORATION to emit light, and then the luminance intensity thereof was measured by using a luminance meter BM-8 manufactured by TOPCON CORPORATION. The light emission spectra and light emission wavelengths were measured by using a spectrum analyzer PMA-11 manufactured by HAMAMATSU PHOTONICS K.K. An external quantum efficiency at a current density of 2.5 mA/cm² was calculated based on these numerical values by means of the luminance conversion method.

(b) Durability

A direct current was adjusted such that an initial luminance became 1,000 cd/m² at room temperature, and a time required until the luminance decreased to a half of the initial value was used as an index of durability.

The obtained results are shown in Tables 1 and 2. Meanwhile, the results of efficiency and durability in Tables 1 and 2 are each described as relative values when the efficiency and durability in Comparative Example A-1 and Comparative Example A-2 are set as 1.

TABLE 1

| | Crosslinking | Efficiency | Durability |
|---|---|---|---|
| | Agent | (Relative value) | (Relative value) |
| Example A-1 | Crosslinking | 2.1 | 4.0 |
| | Agent A | | |
| Example A-2 | Crosslinking | 2.4 | 4.0 |
| | Agent B | | |
| Example A-3 | Crosslinking | 2.6 | 4.1 |
| | Agent C | | |
| Comparative | None | 1.0 | 1.0 |
| Example A-1 | | | |

TABLE 2

| | Crosslinking | Efficiency | Durability |
|---|---|---|---|
| | Agent | (Relative value) | (Relative value) |
| Example A-4 | Crosslinking | 1.2 | 3.9 |
| | Agent A | | |
| Comparative | None | 1.0 | 1.0 |
| Example A-2 | | | |

In addition to what is described above, the structures of compounds used in Examples A-1 to A-4 and Comparative Examples A-1 and A-2 will be described below.

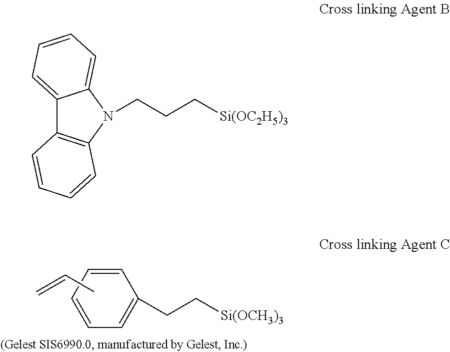

### B. Examples B-1 and B-2 and Comparative Example B-1

### Manufacture of Red Luminescence Device

### Example B-1

### Preparation of Coating Liquid B for Forming Hole Transporting Layer

80% by mass of Siloxane Polymer 1 having NPD at a side chain thereof and 20% by mass of Crosslinking Agent A were dissolved in xylene for electronic industrial use to prepare a solution having a total solid content concentration of 0.4% by mass, and the solution was filtered with a PTFE (polytetrafluoroethylene) filter having a pore size of 0.03 μm, thereby preparing Coating Liquid B for forming a hole transporting layer.

<Preparation of Coating Liquid B for Forming Light Emitting Layer>

90% by mass of Host Compound H-2 and 10% by mass of Light Emitting Material E-2 were dissolved in methyl ethyl ketone (MEK) to prepare a solution having a solid content concentration of 1.0% by mass, and the solution was filtered with a PTFE (polytetrafluoroethylene) filter having a pore size of 0.22 μm, thereby preparing Coating Liquid B for forming a light emitting layer.

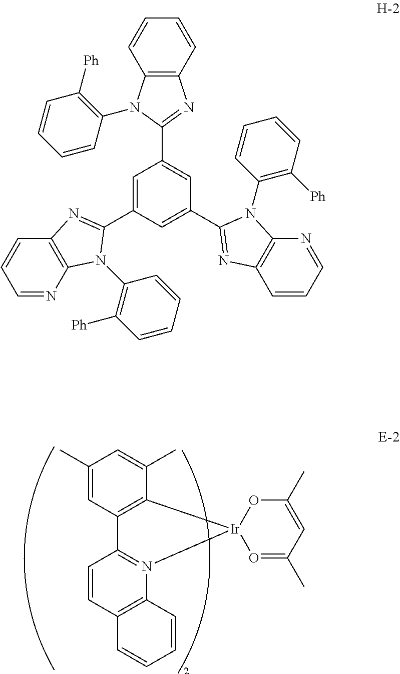

<Manufacture of Device>

On a glass substrate of 25 mm×25 mm×0.7 mm, ITO was subjected to vapor deposition in a thickness of 150 nm to form a film and use the film as a transparent supporting substrate. The transparent supporting substrate was put in a washing vessel, ultrasonically washed in 2-propanpl, and then subjected to a UV-ozone treatment for 30 minutes.

0.5 part by mass of Compound A (described in US2008/0220265) represented by the following structural formula was dissolved in 99.5 parts by mass of cyclohexanone, and the solution was spin coated (4,000 rpm, for 30 seconds) on the glass substrate having the ITO so as to have a thickness of about 5 nm, and then dried at 200° C. for 30 minutes, thereby film-forming a hole injection layer.

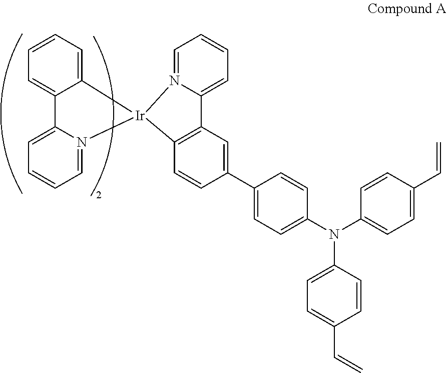

Coating Liquid B for forming a hole transporting layer prepared as described above was spin coated (1,500 rpm, for 20 seconds) on the hole injection layer so as to have a thickness of about 10 nm, and then dried at 120° C. for 30 minutes, thereby film-forming a hole transporting layer.

Coating Liquid B for forming a light emitting layer prepared as described above was spin coated (1,500 rpm, for 20 seconds) on the hole transporting layer so as to have a thickness of about 30 nm within a glove box (dew point of −68° C., oxygen concentration of 10 ppm), thereby preparing a light emitting layer.

Subsequently, BAlq as an electron transporting layer, lithium fluoride (LiF) as an electron injection layer and metallic aluminum as a cathode were film-formed on the light emitting layer in the same manner as in Example A-1.

The laminate thus manufactured was placed in an argon gas-substituted glove box and sealed by using a stainless steel-made sealing can and an ultraviolet ray-curable adhesive (XNR5516HV, manufactured by Nagase Ciba Ltd.), thereby manufacturing Organic Electroluminescence Device B-1.

### Example B-2 and Comparative Example B-1

A device in Example B-2 was obtained in the same manner as in Example B-1, except that in the preparation of Coating Liquid B for forming a hole transporting layer in Example B-1, a crosslinking agent having a content described in the following Table 3 was used and drying during the film-formation of the hole transporting layer was performed at 150° C. for 30 minutes. Further, for comparison, a device in Comparative Example B-1 was obtained in the same manner as in Example B-1, except that a crosslinking agent was not used in the preparation of Coating Liquid B for forming a hole transporting layer in Example B-1.

Each device thus obtained was evaluated in the same manner as in Example A-1, and the results thereof are shown in Table 3. Meanwhile, the results of efficiency and durability in Table 3 are each described as relative values when the efficiency and durability in Comparative Example B-1 are set as 1.

TABLE 3

| | | Crosslinking | Efficiency | Durability |
|---|---|---|---|---|
| | Crosslinking | Agent | (Relative | (Relative |
| | Agent | (Content) | value) | value) |
| Example B-1 | Crosslinking | 20% by mass | 2.1 | 2.0 |
| | Agent A | | | |
| Example B-2 | Crosslinking | 10% by mass | 2.4 | 1.8 |
| | Agent D | | | |
| Comparative | None | 0 | 1.0 | 1.0 |
| Example B-1 | | | | |

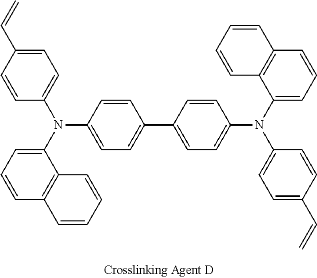 [SMILES: C=Cc1ccc(N(c2ccc(-c3ccc(N(c4ccc(C=C)cc4)c4cccc5ccccc45)cc3)cc2)c2cccc3ccccc23)cc1]

### C. Examples C-1 and C-2 and Comparative Example C-1

### Manufacture of Green Luminescence Device

### Example C-1

### Preparation of Coating Liquid C for Forming Hole Transporting Layer

80% by mass of Siloxane Polymer 1 having NPD at a side chain thereof and 20% by mass of Crosslinking Agent A were dissolved in xylene/benzyl alcohol (=mass ratio 60/40) for electronic industrial use to prepare a solution having a total solid content concentration of 0.4% by mass, and the solution was filtered with a PTFE (polytetrafluoroethylene) filter having a pore size of 0.22 μm, thereby preparing Coating Liquid C for forming a hole transporting layer.

<Preparation of Coating Liquid C for Forming Light Emitting Layer>

95% by mass of Host Compound H-3 and 5% by mass of Light Emitting Material E-3 were dissolved in methyl ethyl ketone (MEK) to prepare a solution having a solid content concentration of 1.0% by mass, and the solution was filtered with a PTFE (polytetrafluoroethylene) filter having a pore size of 0.22 μm, thereby preparing Coating Liquid C for forming a light emitting layer.

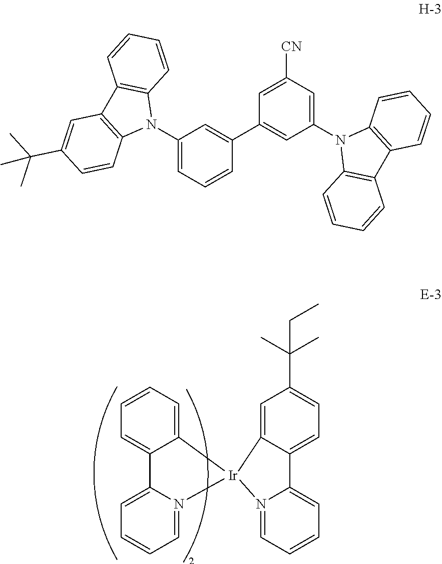

<Manufacture of Device>

A hole injection layer including Compound A was film-formed on a glass substrate having ITO, in the same manner as in Example B-1.

Coating Liquid C for forming a hole transporting layer prepared as described above was spin coated (1,500 rpm, for 20 seconds) on the hole injection layer so as to have a thickness of about 10 nm, dried at 120° C. for 30 minutes, and then subjected to an annealing treatment at 150° C. for 10 minutes, thereby film-forming a hole transporting layer.

Coating Liquid C for forming a light emitting layer prepared as described above was spin coated (1,500 rpm, for 20 seconds) on the hole transporting layer so as to have a thickness of about 30 nm within a glove box (dew point of −68° C., oxygen concentration of 10 ppm), thereby preparing a light emitting layer.

Subsequently, BAlq as an electron transporting layer, lithium fluoride (LiF) as an electron injection layer and metallic aluminum as a cathode were film-formed on the light emitting layer in the same manner as in Example A-1.

The laminate thus manufactured was placed in an argon gas-substituted glove box and sealed by using a stainless steel-made sealing can and an ultraviolet ray-curable adhesive (XNR5516HV, manufactured by Nagase Ciba Ltd.), thereby manufacturing Organic Electroluminescence Device C-1.

### Example C-2 and Comparative Example C-1

A device in Example C-2 was obtained in the same manner as in Example C-1, except that in the preparation of Coating Liquid C for forming a hole transporting layer in Example C-1, a crosslinking agent described in the following Table 4 was used. Further, for comparison, a device in Comparative Example C-1 was obtained in the same manner as in Example C-1, except that a crosslinking agent was not used in the preparation of Coating Liquid C for forming a hole transporting layer in Example C-1.

Each device thus obtained was evaluated in the same manner as in Example A-1, and the results thereof are shown in Table 4. Meanwhile, the results of efficiency and durability in Table 4 are each described as relative values when the efficiency and durability in Comparative Example C-1 are set as 1.

TABLE 4

| | Crosslinking | Efficiency | Durability |
|---|---|---|---|
| | Agent | (Relative value) | (Relative value) |
| Example C-1 | Crosslinking | 2.7 | 2.0 |
| | Agent A | | |
| Example C-2 | Crosslinking | 3.2 | 3.6 |
| | Agent E | | |
| Comparative | None | 1.0 | 1.0 |
| Example C-1 | | | |

In addition to what is described above, the structures of compounds used in Example C-2 will be described below.

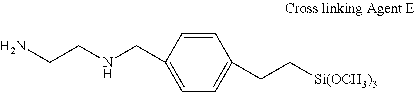

### D. Examples D-1 and D-2 and Comparative Example D-1

### Manufacture of Green Luminescence Device

### Example D-1

### Preparation of Coating Liquid D for Forming Hole Transporting Layer

2 parts by mass of Compound B was dissolved in 98 parts by mass of dehydrated toluene (manufactured by Kanto Chemical Industry Co., Ltd.) to prepare a solution, and the solution was filtered with a PTFE (polytetrafluoroethylene) filter having a pore size of 0.22 μm, thereby preparing Coating Liquid D for forming a hole transporting layer.

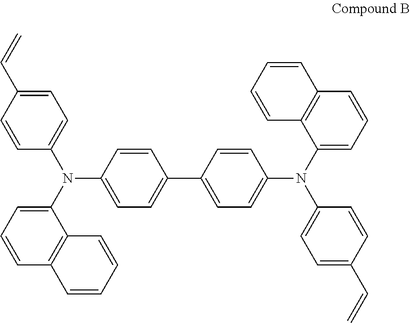 [SMILES: C=Cc1ccc(N(c2ccc(-c3ccc(N(c4ccc(C=C)cc4)c4cccc5ccccc45)cc3)cc2)c2cccc3ccccc23)cc1]

<Preparation of Coating Liquid D for Forming Exciton Blocking Layer>

90% by mass of Siloxane Polymer 2 having carbazole at a side chain thereof and 10% by mass of Crosslinking Agent A were dissolved in xylene for electronic industrial use to prepare a solution having a total solid content concentration of 0.4% by mass, and the solution was filtered with a PTFE (polytetrafluoroethylene) filter having a pore size of 0.22 μm, thereby preparing Coating Liquid D for forming an exciton blocking layer.

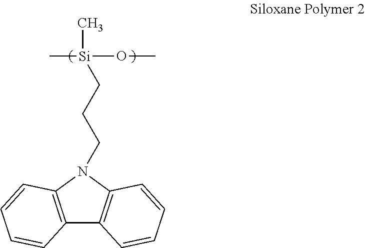 [SMILES: CO[Si](C)(C)CCCn1c2ccccc2c2ccccc21]

<Manufacture of Device>

A hole injection layer including Compound A was film-formed on a glass substrate having ITO, in the same manner as in Example B-1.

Coating Liquid D for forming a hole transporting layer prepared as described above was spin coated (4,000 rpm, for 30 seconds) on the hole injection layer so as to have a thickness of about 18 nm, and then dried at 200° C. for 30 minutes, thereby film-forming a hole transporting layer.

Coating Liquid D for forming an exciton blocking layer prepared as described above was spin coated (3,000 rpm, for 20 seconds) on the hole transporting layer so as to have a thickness of about 5 nm, dried at 120° C. for 30 minutes, and then subjected to an annealing treatment at 150° C. for 10 minutes, thereby film-forming an exciton blocking layer.

A light emitting layer was film-formed on the exciton blocking layer by means of a vacuum vapor deposition method, in the same manner as in Example A-4.

Subsequently, BAlq as an electron transporting layer, lithium fluoride (LiF) as an electron injection layer and metallic aluminum as a cathode were film-formed on the light emitting layer in the same manner as in Example A-1.

The laminate thus manufactured was placed in an argon gas-substituted glove box and sealed by using a stainless steel-made sealing can and an ultraviolet ray-curable adhesive (XNR5516HV, manufactured by Nagase Ciba Ltd.), thereby manufacturing Organic Electroluminescence Device D-1.

### Example D-2 and Comparative Example D-1

A device in Example D-2 was obtained in the same manner as in Example D-1, except that in the preparation of Coating Liquid D for forming an exciton blocking layer in Example D-1, a crosslinking agent described in the following Table 5 was used. In addition, for comparison, a device in Comparative Example D-1 was obtained in the same manner as in Example D-1, except that a crosslinking agent was not used in the preparation of Coating Liquid D for forming an exciton blocking layer in Examples D-1.

Each device thus obtained was evaluated in the same manner as in Example A-1, and the results thereof are shown in Table 5. Meanwhile, the results of efficiency and durability in Table 5 are each described as relative values when the efficiency and durability in Comparative Example D-1 are set as 1.

TABLE 5

| | Crosslinking | Efficiency | Durability |
|---|---|---|---|
| | Agent | (Relative value) | (Relative value) |
| Example D-1 | Crosslinking | 2.0 | 1.6 |
| | Agent A | | |
| Example D-2 | Crosslinking | 1.5 | 1.4 |
| | Agent E | | |
| Comparative | None | 1.0 | 1.0 |
| Example D-1 | | | |

As obvious from the results of Tables 1 to 5, it can be known that efficiency and durability have been improved in the devices in the Examples, in which a composition containing a siloxane polymer having a charge transporting moiety at a side chain thereof, at least one crosslinking agent and a solvent is used, compared to the devices in the Comparative Examples, in which the composition of the present invention is not used.

### INDUSTRIAL APPLICABILITY

According to the present invention, it is possible to provide a composition useful for manufacturing an organic electroluminescence device that has improved efficiency and durability in an organic electroluminescence device in which a siloxane polymer is used as a material for organic electroluminescence device.

Further, according to the present invention, it is possible to provide a film using the composition, a charge transporting layer, an organic electroluminescence device, and a method for forming a charge transporting layer.

Although the present invention has been described with reference to detailed and specific embodiments thereof, it is obvious to those skilled in the art that various changes or modifications may be made without departing from the spirit and scope of the present invention.

The present application is based on Japanese Patent Application 2010-150596 filed on Jun. 30, 2010, the content of which is incorporated herein by reference.

### REFERENCE SIGNS LIST

2 Substrate
3 Anode
4 Hole injection layer
5 Hole transporting layer
6 Light emitting layer
7 Hole blocking layer
8 Electron transporting layer
9 Cathode
10 Organic electroluminescence device

1. A composition comprising:
(A) a siloxane polymer having a charge transporting moiety at a side chain thereof;
(B) at least one crosslinking agent; and
(C) a solvent.

2. The composition of claim 1,
wherein the at least one crosslinking agent (B) comprises an alkoxylsilane compound or a chlorosilane compound.

3. The composition of claim 2,
wherein the alkoxysilane compound or the chlorosilane compound has a charge transporting moiety.

4. The composition of claim 2,
wherein the alkoxysilane compound or the chlorosilane compound has a vinyl group.

5. The composition of claim 1,
wherein the at least one crosslinking agent (B) comprises a compound having a plurality of vinyl groups.

6. The composition of claim 5,
wherein the compound having a plurality of vinyl groups further has a charge transporting moiety.

7. The composition of claim 1,
wherein the charge transporting moiety of the side chain of the siloxane polymer (A) is a hole transporting moiety.

8. The composition of claim 1,
wherein the solvent (C) contains an aromatic hydrocarbon-based solvent as a first solvent, and a second solvent having a relative permittivity higher than that of the first solvent.

9. A film formed by applying the composition of claim 1 and heating the applied composition.

10. A charge transporting layer which is the film of claim 9.

11. An organic electroluminescence device comprising the charge transporting layer of claim 10.

12. A method for forming a charge transporting layer, comprising:
applying the composition of claim 1; and
heating the applied composition.
